(19) United States
(12) Patent Application Publication
(10) Pub. No.: US 2022/0028877 A1
(43) Pub. Date: Jan. 27, 2022

(54) INTEGRATED CIRCUIT DEVICES WITH HIGHLY INTEGRATED MEMORY AND PERIPHERAL CIRCUITS THEREIN

(71) Applicant: Samsung Electronics Co., Ltd., Suwon-si (KR)

(72) Inventors: Changsun Hwang, Hwaseong-si (KR); Gihwan Kim, Suwon-si (KR); Hansol Seok, Hwaseong-si (KR); Jongheun Lim, Seoul (KR); Kiseok Jang, Gimhae-si (KR)

(21) Appl. No.: 17/204,380

(22) Filed: Mar. 17, 2021

(51) Int. Cl. H01L 27/11573; H01L 23/535; H01L 27/11556; H01L 27/11529; H01L 27/11582

(52) U.S. Cl. CPC H01L 27/11573; H01L 23/535; H01L 27/11582; H01L 27/11529; H01L 27/11556

(57) ABSTRACT

An integrated circuit device includes a vertical stack of nonvolatile memory cells on a substrate, which are configured as a vertical NAND string of memory cells. This vertical stack of nonvolatile memory cells includes a plurality of gate patterns, which are spaced apart from each other by corresponding electrically insulating layers. A dummy mold structure is also provided on the substrate. The dummy mold structure includes a vertical stack of sacrificial layers, which are spaced apart from each other by corresponding electrically insulating layers. An insulation pattern is provided, which fills a dish-shaped recess in a first one of the sacrificial layers in the vertical stack of sacrificial layers. This insulation pattern has an upper surface that is coplanar with an upper surface of the first one of the sacrificial layers.

### REFERENCE TO PRIORITY APPLICATION

This application claims priority under 35 USC § 119 to Korean Patent Application No. 10-2020-0093215, filed Jul. 27, 2020, the contents of which are hereby incorporated herein by reference.

### BACKGROUND

### 1. Field

Example embodiments relate to integrated circuit devices and, more particularly, to integrated circuit devices having vertically and highly integrated semiconductor devices therein and methods of forming same.

### 2. Description of the Related Art

As semiconductor devices become more highly integrated, a VNAND flash memory device may utilize a cell-on-peripheral (COP) structure in which a peripheral circuit is formed on a substrate and cell stack structures including memory cells are stacked on the peripheral circuit. An insulating interlayer may be formed between the cell stack structures. As a height in a vertical direction of the cell stack structure increases, a planarization process of an upper surface of the insulating interlayer may be difficult. Thus, a dishing defect associated with the upper surface of the insulating interlayer may occur.

### SUMMARY

Example embodiments of the invention provide highly integrated vertical semiconductor devices with reduced susceptibility to process and other manufacturing defects.

According to some example embodiments, there is formed a vertical memory device that may include circuit patterns, a lower insulating interlayer, base semiconductor patterns, a memory cell stack structure, and a dummy mold structure. The circuit patterns may be formed on a substrate. The lower insulating interlayer may cover the circuit patterns. The base semiconductor patterns may be formed on the lower insulating interlayer. The base semiconductor patterns may be spaced apart from each other to form a first opening between the base semiconductor patterns. The memory cell stack structure may be formed on the base semiconductor patterns. The dummy mold structure may be formed on the base semiconductor patterns and the first opening. The dummy mold structure may be spaced apart from the memory cell stack structure. The dummy mold structure may include a first dummy mold structure, a first lower insulation pattern, and an upper dummy mold structure. The first dummy mold structure may include first insulation layers and first sacrificial layers, which are alternately stacked, and the upper surfaces and the lower surfaces of the first insulation layers and the first sacrificial layers may not be sufficiently planar. For example, a center portion of an upper surface of the first dummy mold structure may have a dishing portion (e.g., a dish-shaped cross-section). The first lower insulation pattern may completely fill the dishing portion (i.e., recess with sloped sidewalls) in an upper surface of the first dummy mold structure. And, the upper dummy mold structure may be formed on the first dummy mold structure and the first lower insulation pattern, which has a planar upper surface with the upper surface of the first dummy mold structure. The upper dummy mold structure may include second insulation layers and second sacrificial layers, which are alternately stacked, and upper surfaces and lower surfaces of the second insulation layers and the second sacrificial layers may be substantially planar (e.g., flat).

According to other example embodiments, there is formed a vertical memory device having circuit patterns, a lower insulating interlayer, base semiconductor patterns, a memory cell stack structure, a channel structure, a dummy mold structure and a lower insulation pattern. The circuit patterns may be formed on a substrate. The lower insulating interlayer may cover the circuit patterns. The base semiconductor patterns may be formed on the lower insulating interlayer. The base semiconductor patterns are spaced apart from each other to form a first opening between the base semiconductor patterns. The memory cell stack structure may be formed on the base semiconductor patterns. The channel structure may be formed in a channel hole passing through the memory cell stack structure. The channel structure may include a channel electrically connected to the base semiconductor patterns. The dummy mold structure may be formed on the base semiconductor patterns and the first opening. The dummy mold structure may be spaced apart from the memory cell stack structure. The lower insulation pattern may fill a space between the memory cell stack structure and the dummy mold structure. Upper surfaces of the memory cell stack structure, the dummy mold structure, and the lower insulation pattern may be substantially coplanar with each other. The dummy mold structure may include a first dummy mold structure, a first lower insulation pattern and an upper dummy mold structure. The first dummy structure may include first insulation layers and first sacrificial layers, which are alternately stacked, and upper surfaces and the lower surfaces of the first insulation layers and the first sacrificial layers may not be planar. A center portion of an upper surface of the first dummy mold structure may also include a dishing portion (e.g., dish-shaped recess). The first lower insulation pattern may fill the dishing portion of an upper surface of the first dummy mold structure. The upper dummy mold structure may be formed on the first dummy mold structure and the first lower insulation pattern. The upper dummy mold structure may include second insulation layers and second sacrificial layers, which are alternately stacked. Upper surfaces and lower surfaces of the second insulation layers and the second sacrificial layers may be substantially planar.

According to example embodiments, there is formed a vertical memory device that may include circuit patterns, a lower insulating interlayer, base semiconductor patterns, a memory cell stack structure, a channel structure, a dummy mold structure and a lower insulation pattern. The circuit patterns may be formed on a substrate. The lower insulating interlayer may cover the circuit patterns. The base semiconductor patterns may be formed on the lower insulating interlayer. The base semiconductor patterns may be spaced apart from each other to form a first opening between the base semiconductor patterns. The memory cell stack structure may be formed on the base semiconductor patterns. The channel structure may be formed in a channel hole passing through the memory cell stack structure. The channel structure may include a channel electrically connected to the base semiconductor patterns. The dummy mold structure may be formed on the base semiconductor patterns and the first opening. The dummy mold structure may be spaced apart from the memory cell stack structure. The lower insulation pattern may fill a space between the memory cell stack structure and the dummy mold structure. Upper surfaces of the memory cell stack structure, the dummy mold structure, and the lower insulation pattern may be substantially coplanar with each other. The dummy mold structure may include insulation layers and the sacrificial layers, which are alternately stacked. Upper surfaces and the lower surfaces of the insulation layers and the sacrificial layers in a lower portion of the dummy mold structure may not be entirely planar, and the lower portion of the dummy mold structure may have a dishing portion at a portion facing the first opening.

In additional example embodiments, a vertical semiconductor device may include the memory cell stack structure and the dummy mold structure spaced apart from the memory cell stack structure. Thus, a dishing defect within the upper surface of the lower insulation pattern between the memory cell stack structure and the dummy mold structure may be prevented. In addition, the sacrificial layers in an upper portion of the dummy mold structure may have flat upper surfaces and flat lower surfaces. Thus, a dishing defect of an upper surface of the dummy mold structure may not occur. In the vertical semiconductor device according to embodiments of the invention, failures due to a dishing defect(s) may be decreased.

### BRIEF DESCRIPTION OF THE DRAWINGS

Example embodiments will be more clearly understood from the following detailed description taken in conjunction with the accompanying drawings. FIGS. 1 to 22 represent non-limiting, example embodiments as described herein.

FIG. 1 is a cross-sectional view illustrating a vertical semiconductor device in accordance with example embodiments;

FIG. 2 is a cross-sectional view illustrating a vertical semiconductor device in accordance with some example embodiments;

FIGS. 3 to 13 are cross-sectional views illustrating a method of manufacturing a vertical semiconductor device in accordance with example embodiments;

FIG. 14 is a cross-sectional view of a semiconductor device in accordance with example embodiments;

FIGS. 15 and 16 are cross-sectional views illustrating a method of manufacturing a vertical semiconductor device in accordance with example embodiments;

FIG. 17 is a cross-sectional view of a semiconductor device in accordance with example embodiments; and

FIGS. 18 to 22 are cross-sectional views illustrating a method of manufacturing a vertical semiconductor device in accordance with example embodiments.

### DESCRIPTION OF EMBODIMENTS

Hereinafter, a direction substantially perpendicular to an upper surface of the substrate is defined as a vertical direction, and two directions crossing with each other in horizontal directions substantially parallel to the upper surface of the substrate are defined as first and second directions, respectively. In example embodiments, the first and second directions may be perpendicular to each other.

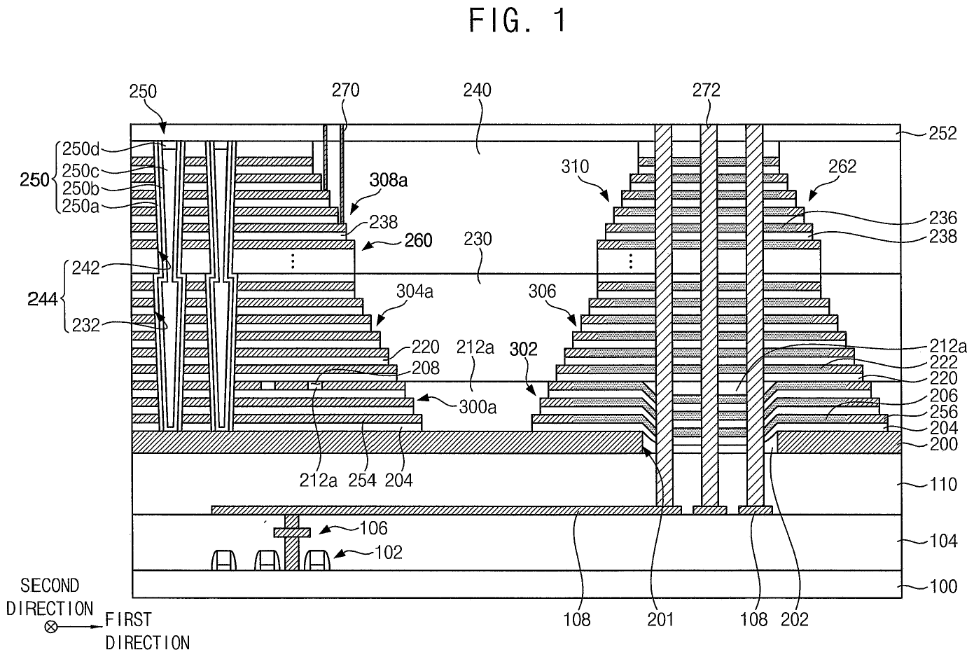

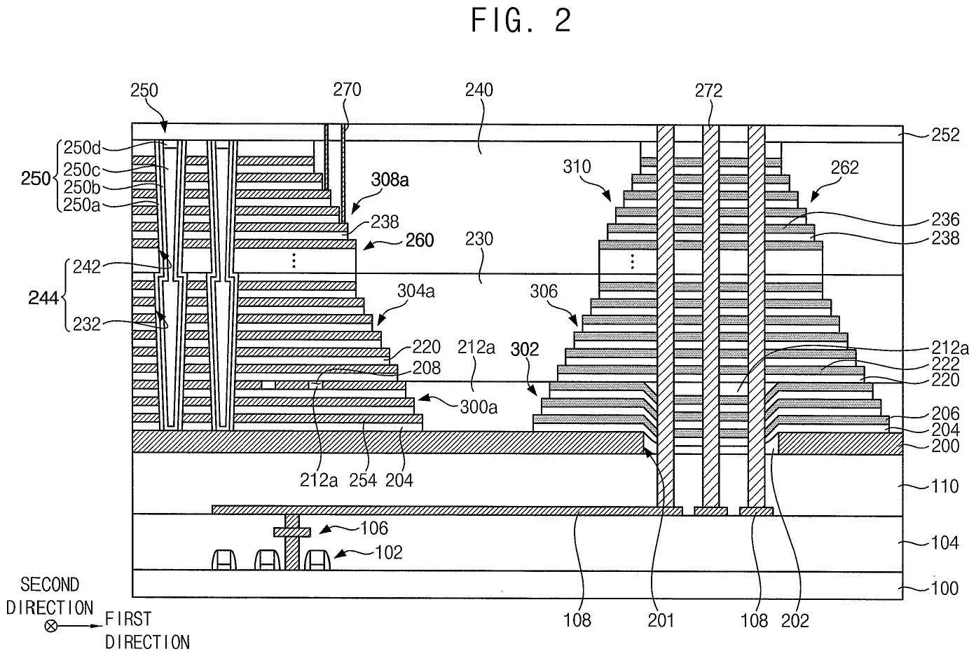

FIG. 1 is a cross-sectional view illustrating a vertical semiconductor device in accordance with example embodiments. FIG. 2 is a cross-sectional view illustrating a vertical semiconductor device in accordance with some example embodiments. Referring to FIG. 1, the vertical semiconductor device may include circuit patterns constituting a peripheral circuit on a substrate 100. In example embodiments, the circuit pattern may include lower transistors 102 and lower wiring 106. The lower wiring 106 may include lower contact plugs and lower conductive patterns. The lower wiring 106 may be electrically connected to the lower transistors 102.

The substrate 100 may include a single crystal semiconductor material. For example, the substrate 100 may include silicon, germanium, and silicon-germanium. The substrate 100 may include a first region in which a memory cell stack structure may be formed and a second region in which the memory cell stack structure may not be formed. A first lower insulating interlayer 104 covering the circuit patterns may be formed on the substrate 100. A lower pad pattern 108 may be formed on the first lower insulating interlayer 104. A second lower insulating interlayer 110 may be formed on the first lower insulating interlayer 104 and the lower pad pattern 108. An upper surface of the second lower insulating interlayer 110 may be substantially flat.

In example embodiments, the lower pad pattern 108 may be electrically connected to the lower transistors 102 via the lower contact plug and lower conductive patterns. In addition, a plurality of base semiconductor patterns 200 may be formed on the second lower insulating interlayer 110. The base semiconductor patterns 200 may include polysilicon. A first opening 201 may be included between the base semiconductor patterns 200.

In some example embodiments, the base semiconductor pattern 200 may be disposed to face in the vertical direction a portion for forming the memory cell stack structure 260. The first opening 201 may be disposed to face in the vertical direction a portion for forming the through via contact 272. In other example embodiments, the first opening 201 may be formed at an outside of the memory cell stack structure 260, and thus the first opening 201 may be spaced from the memory cell stack structure 260. A width in the first direction of the first opening 201 may be about 5 μm to about 200 μm. In example embodiments, the first opening 201 may include a plurality of first openings. And, in some other example embodiments, although not shown, some of the first openings 201 may be formed to be opposite a stepped portion of an edge of the memory cell stack structure 260.

A lower filling pattern 202 may be formed on the second lower insulating interlayer 110 in the first opening 201. An upper surface of the lower filling pattern 202 may not be flat, and the upper surface of the lower filling pattern 202 may include a dishing portion in which a center portion of the upper surface may be recessed. As the width in the first direction of the first opening 201 increases, a difference between a lowermost portion of the upper surface of the lower filling pattern 202 and an uppermost portion of the upper surface of the lower filling pattern 202 may increase. For example, the difference between a lowermost portion of the upper surface of the lower filling pattern 202 and an uppermost portion of the upper surface of the lower filling pattern 202 may be about 300 Å or more.

The upper surface of the base semiconductor pattern 200 and the upper surface of the lower filling pattern 202 may not necessarily be coplanar with each other. For example, the upper surface of the lower filling pattern 202 may be lower than the upper surface of the base semiconductor pattern 200. The memory cell stack structure 260 may be formed on the base semiconductor pattern 200 in the first region, and the dummy mold structure 262 may be formed on the base semiconductor pattern 200 and the lower filling pattern 202 in the second region.

The memory cell stack structure 260 may include a first memory cell stack structure 300a, a second memory cell stack structure 304a, and a third memory cell stack structure 308a sequentially stacked. The dummy mold structure 262 may include a first dummy mold structure 302, a second dummy mold structure 306, and a third dummy mold structure 310 sequentially stacked. The second memory cell stack structure 304a and the third memory cell stack structure 308a may be referred to as an upper memory cell stack structure. The second dummy mold structure 306 and the third dummy mold structure 310 may be referred to as an upper dummy mold structure.

The memory cell stack structure 260 may have a structure in which insulation layers 204, 220, 238 and gate patterns 254 may be alternately and repeatedly stacked. The memory cell stack structure 260 may extend in the first direction, and an edge portion in the first direction of the memory cell stack structure 260 may have a staircase shape. An edge portion in the first direction of one of the gate patterns 254 may protrude in the first direction from an edge portion in the first direction of a gate pattern thereon.

The insulation layers 204, 220, 238 may include silicon oxide. Each of the gate patterns 254 may include a barrier metal pattern and a metal pattern. The barrier metal pattern may surround a surface of the metal pattern. The barrier metal pattern may include titanium, titanium nitride, tantalum, tantalum nitride, or the like. The metal pattern may include a material such as tungsten, copper, or aluminum. For example, the metal pattern may include tungsten.

The dummy mold structure 262 may include a structure in which the insulation layers 204, 220, 238 and sacrificial layers 206, 222, 236 may be alternately and repeatedly stacked. An edge portion in the first direction of the dummy mold structure 262 may have a staircase shape. The insulation layers 204, 220, 238 may include silicon oxide. The sacrificial layers 206, 222, and 236 may include silicon nitride.

In example embodiments, as shown in FIG. 1, the dummy mold structure 262 may include a structure in which the insulation layers 204, 220, 238 and sacrificial layers 206, 222, and 236 may be alternately stacked. In addition, the conductive patterns 256 may be further included at an edge portion of the dummy mold structure 262. That is, in the edge portion of the dummy mold structure 262, portions of the sacrificial layers 206, 222, and 236 may be replaced with the conductive pattern 256.

In some example embodiments, as shown in FIG. 2, the dummy mold structure 262 may include a structure in which the insulation layers 204, 220, 238 and sacrificial layers 206, 222, 236 may be alternately and repeatedly stacked. However, the conductive patterns may not be included at the edge portion of the dummy mold structure 262.

In other example embodiments, the first memory cell stack structure 300a may include first insulation layers 204 and gate patterns 254, which may be repeatedly stacked. The gate patterns 254 in the first memory cell stack structure 300a may serve as gate patterns of a ground selection transistor and at least one transistor disposed below the ground selection transistor. For example, the gate patterns 254 in the first memory cell stack structure 300a may serve as the gate patterns of the ground selection transistor and gate patterns of GIDL transistors.

In example embodiments, an uppermost gate pattern in the first memory cell stack structure 300a may serve as the gate pattern of the ground selection transistor. The uppermost gate pattern in the first memory cell stack structure 300a may include at least one cutting portion. The cutting portion, which is a portion cut off the uppermost gate pattern may serve as a ground line cutting region 208. In example embodiments, a width of the ground line cutting region 208 may be about 0.5 μm to about 5 μm. The ground line cutting region 208 may be disposed at a wiring connection portion, which is a portion having the staircase shape in the memory cell stack structure 260. That is, the ground line cutting region 208 may not be disposed at a portion where memory cells are formed. The ground line cutting region 208 may not be disposed at a portion where channel structures are formed.

In example embodiments, the first dummy mold structure 302 may have a structure in which first insulation layers 204 and first sacrificial layers 206 may be alternately and repeatedly stacked. The first dummy mold structure 302 may be formed on the base semiconductor pattern 200 and the lower filling pattern 202 in the second region. The upper surface of the lower filling pattern 202 may be lower than the upper surface of the base semiconductor pattern 200. Therefore, upper surfaces and lower surfaces of the first insulation layers 204 and the first sacrificial layers 206 included in the first dummy mold structure 302 may not be entirely planar. In the first dummy mold structure 302, the upper surfaces and the lower surfaces of the first insulation layers 204 and the first sacrificial layers 206 on the base semiconductor pattern 200 may be relatively high, and the upper surfaces and the lower surfaces of the first insulation layers 204 and the first sacrificial layers 206 on the lower filling pattern 202 may be relatively low. That is, in the first dummy mold structure 302, the upper surfaces and the lower surfaces of the first insulation layers 204 and the first sacrificial layers 206 on the base semiconductor pattern 200 may be higher than the upper surfaces and the lower surfaces of the first insulation layers 204 and the first sacrificial layers 206 on the lower filling pattern 202. Thus, a dishing portion (e.g., dish-shaped recess with sloped sidewalls) may be formed on a center portion of an upper surface of the first dummy mold structure 302 facing the lower filling pattern 202.

A first lower insulation pattern 212a may be formed on the base semiconductor pattern 200 to fill a space between the first memory cell stack structure 300a and the first dummy mold structure 302. The first lower insulation pattern 212a may cover sidewalls of the first memory cell stack structure 300a and the first dummy mold structure 302. The first lower insulation pattern 212a may include silicon oxide.

The first lower insulation pattern 212a may be also formed on an upper surface of the first dummy mold structure 302 facing the lower filling pattern 202. Thus, the first lower insulation pattern 212a may fill the dishing portion (i.e., recess) in the upper surface of the first dummy mold structure 302. Further, the first lower insulation pattern 212a may fill an inner portion of the ground line cutting region 208.

Therefore, upper surfaces of the first memory cell stack structure 300a, the first dummy mold structure 302, and the first lower insulation pattern 212a may be substantially planar. The upper surfaces of the first memory cell stack structure 300a, the first dummy mold structure 302, and the first lower insulation pattern 212a may be coplanar with each other.

In example embodiments, the second memory cell stack structure 304a may include second insulation layers 220 and gate patterns 254 repeatedly stacked. The gate patterns 254 included in the second memory cell stack structure 304a may serve as gate patterns of cell transistors, respectively.

In example embodiments, the second dummy mold structure 306 may include a structure in which the second insulation layer 220 and the second sacrificial layer 222 may be alternately and repeatedly stacked. The second dummy mold structure 306 may be formed on the first dummy mold structure 302 and the first lower insulation pattern 212a. The upper surfaces of the first dummy mold structure 302 and the first lower insulation pattern may be substantially planar (e.g., flat). Therefore, upper and lower surfaces of the second insulation layer 220 and the second sacrificial layer 222 included in the second dummy mold structure 306 may also be substantially planar. Thus, a dishing portion may not include at the upper surface of the second dummy mold structure 306 facing the lower filling pattern 202.

A second lower insulation pattern 230 may be formed on the first lower insulation pattern 212a to fill a space between the second memory cell stack structure 304a and the second dummy mold structure 306. The second lower insulation pattern 230 may cover sidewalls of the second memory cell stack structure 304a and the second dummy mold structure 306. The second lower insulation pattern 230 may include silicon oxide.

Upper surfaces of the second memory cell stack structure 304a, the second dummy mold structure 306, and the second lower insulation pattern 230 may be substantially flat. The upper surfaces of the second memory cell stack structure 304a, the second dummy mold structure 306, and the second lower insulation pattern 230 may be coplanar with each other.

In example embodiments, the third memory cell stack structure 308a may include a structure in which third insulation layers 238 and gate patterns 254 are repeatedly and alternately stacked. The gate patterns 254 included in the third memory cell stack structure 308a may serve as gate patterns of the cell transistors and a gate pattern of a string selection transistor.

In example embodiments, the third dummy mold structure 310 may have a structure in which the third insulation layer 238 and the third sacrificial layer 236 may be alternately and repeatedly stacked. The third dummy mold structure 310 may be formed on the second dummy mold structure 306 and the second lower insulation pattern 230. Upper surfaces of the second dummy mold structure 306 and the second lower insulation pattern 230 may be substantially flat. Therefore, upper and lower surfaces of the third insulation layer 238 and the third sacrificial layer 236 included in the third dummy mold structure 310 may be substantially flat. Thus, a dishing portion may not be formed on the upper surface of the third dummy mold structure 310, which faces the lower filling pattern 202.

A third lower insulation pattern 240 may be formed on the second lower insulation pattern 230 to fill a space between the third memory cell stack structure 308a and the third dummy mold structure 310. The third lower insulation pattern 240 may cover sidewalls of the third memory cell stack structure 308a and the third dummy mold structure 310. The third lower insulation pattern 240 may include silicon oxide.

Upper surfaces of the third memory cell stack structure 308a, the third dummy mold structure 310, and the third lower insulation pattern 240 may be substantially flat. The upper surfaces of the third memory cell stack structure 308a, the third dummy mold structure 310, and the third lower insulation pattern 240 may be coplanar with each other.

In example embodiments, the number of stacked gate patterns 254 included in the memory cell stack structure 260 may be the same as the number of stacked sacrificial layers 206, 222, 236 included in the dummy mold structure 262. Further, the gate patterns 254 included in the second and third memory cell stack structures 304a and 308a and the sacrificial layers 206, 222, 236 included in the dummy mold structure 262 may be positioned at the same levels in the vertical direction, respectively.

If the first to third dummy mold structures 302, 306, and 310 are not formed, upper surfaces of the second and third lower insulation patterns 230 formed at outside the memory cell stack structure 260 may be further removed during a planarization process. Thus, dishing portions may be formed on the upper surfaces of the second and third lower insulation patterns 230 and 240. However, in example embodiments, the first to third dummy mold structures 302, 306, and 310 may be formed, so that dishing defects may be prevented on upper surfaces of the second and third lower insulation patterns 230 and 240. Therefore, the upper surface of the third lower insulation pattern 240 may not be disposed lower than the upper surface of the memory cell stack structure 260. The upper surface of the third lower insulation pattern 240 may be coplanar with the upper surface of the memory cell stack structure 260.

The first lower insulation pattern 212a may completely fill the dishing portion of the upper surface of the first dummy mold structure 302. Thus, upper and lower surfaces of the sacrificial layers 222 and 236 included in the second and third dummy mold structures 306 and 310 may be substantially planar, and defects (e.g., unstable of the dummy mold structure and process failure of the semiconductor device) that may occur due to uneven upper and lower surfaces may be decreased.

The dummy mold structure 262 may prevent the upward penetration of hydrogen and/or boron included in the first and second lower insulating interlayers 104 and 110 (covering the circuit patterns) into upper layers. That is, the dummy mold structure 262 may also serve as a barrier structure for preventing the upward penetration of hydrogen and boron. As the penetration of hydrogen and boron is prevented by the dummy mold structure 262, standby currents and leakage currents generated in the circuit patterns may be decreased.

Channel holes 244 may be formed through the memory cell stack structure 260 to expose an upper surface of the base semiconductor pattern 200. A channel structure 250 may be formed in each of the channel holes 244. The channel hole 244 may include a lower channel hole 232 and an upper channel hole 242. The lower channel hole 232 and the upper channel hole 242 may be communicated with each other in the vertical direction. The lower channel hole 232 may pass through the second memory cell stack structure 304a and the first memory cell stack structure 300a to expose an upper surface of the base semiconductor pattern 200. The upper channel hole 242 may be disposed on the lower channel hole 232, and may pass through the third memory cell stack structure 308a.

The channel structure 250 may include a charge storage structure 250a, a channel 250b, a filling insulation pattern 250c, and a capping pattern 250d. In addition, the charge storage structure 250a may contact a sidewall of the channel hole 244. The charge storage structure 250a may include a blocking layer, a charge storage layer, and a tunnel insulation layer sequentially stacked on the sidewall of the channel hole 244. The channel 250b may contact the tunnel insulation layer, and may be electrically connected to the base semiconductor pattern 200.

In example embodiments, the channel 250b may directly contact the base semiconductor pattern 200. In some example embodiments, a channel connection pattern (not shown) may be further formed on the base semiconductor pattern 200, and a sidewall of the channel may contact the channel connection pattern. The filling insulation pattern 250c may be formed on the channel 250b, and may fill the channel hole 244. The capping pattern 250d may be formed on the filling insulation pattern 250c, and may be electrically connected to the channel 250b.

A first insulating interlayer 252 may be formed on the third memory cell stack structure 308a, the channel structure 250, the third dummy mold structure 310, and the third lower insulation pattern 240. The first insulating interlayer 252 may include silicon oxide. The first to third lower insulation patterns 212a, 230, and 240 may be stacked between the memory cell stack structure 260 and the dummy mold structure 262. The first to third lower insulation patterns 212a, 230, and 240 may include the same material (e.g., silicon oxide). Therefore, the first to third lower insulation patterns 212a, 230, and 240 may be merged, and may be referred to as a lower insulation pattern.

Cell contact plugs may contact upper surfaces of the gate pattern 254 at an edge of the cell stack structure 260, respectively. The cell contact plugs may pass through the first insulating interlayer 252 and the lower insulation patterns 212a, 230, and 240. However, in order to avoid a complexity of the drawing, only some of the cell contact plugs 270 are shown. A through via contact 272 may contact the lower pad pattern 108 through the dummy mold structure 262, the lower filling pattern 202, and the second lower insulating interlayer 110. The through via contact 272 may be electrically connected to circuit patterns.

The through via contact 272 may pass through a portion of the dummy mold structure 262 facing the first opening 201. In addition, the through via contact 272 may pass through an inner portion of the first opening 201 between the base semiconductor patterns 200. Therefore, the through via contact 272 may pass through dishing portions of the first sacrificial layers 206 in the first dummy mold structure 302. In example embodiments, one or more through via contacts 272 may be formed through the dummy mold structure 262. In other example embodiments, the conductive patterns 256 may include at an edge of the dummy mold structure 262. The conductive patterns 256 included in the dummy mold structure 262 may be spaced apart from the through via contact 272, without contacting the through via contact 272.

As described above, the vertical semiconductor device may include the cell stack structure 260 and the dummy mold structure 262 disposed outside the cell stack structure 260. The dummy mold structure 262 may include the first dummy mold structure 302 disposed at a lower portion, and the upper surfaces and lower surfaces of the first sacrificial layers 206 included in the first dummy mold structure 302 may not be substantially planar. The upper surfaces of the first sacrificial layers 206 may include dishing portions, which define dish-shaped recesses. However, the upper and lower surfaces of the second and third sacrificial layers 222 and 236 included in the second and third dummy mold structures 306 and 310 on the first dummy mold structure 302 may be substantially planar. Thus, a top surface of the dummy mold structure 262 may not include the dishing portion. In addition, upper surfaces of the cell stack structure 260, the dummy mold structure 262, and the lower insulation pattern therebetween may be substantially planar. The upper surfaces of the cell stack structure 260, the dummy mold structure 262, and the lower insulation pattern may be coplanar with each other.

In the vertical semiconductor device, failures due to dishing defects of the upper surfaces of the dummy mold structure 262 and/or the third lower insulation pattern 240 may be decreased. In addition, the dummy mold structure 262 may be formed over the circuit patterns, so that the standby-currents and leakage currents generated in the circuit pattern may be decreased. Therefore, the vertical semiconductor device may have excellent electrical characteristics.

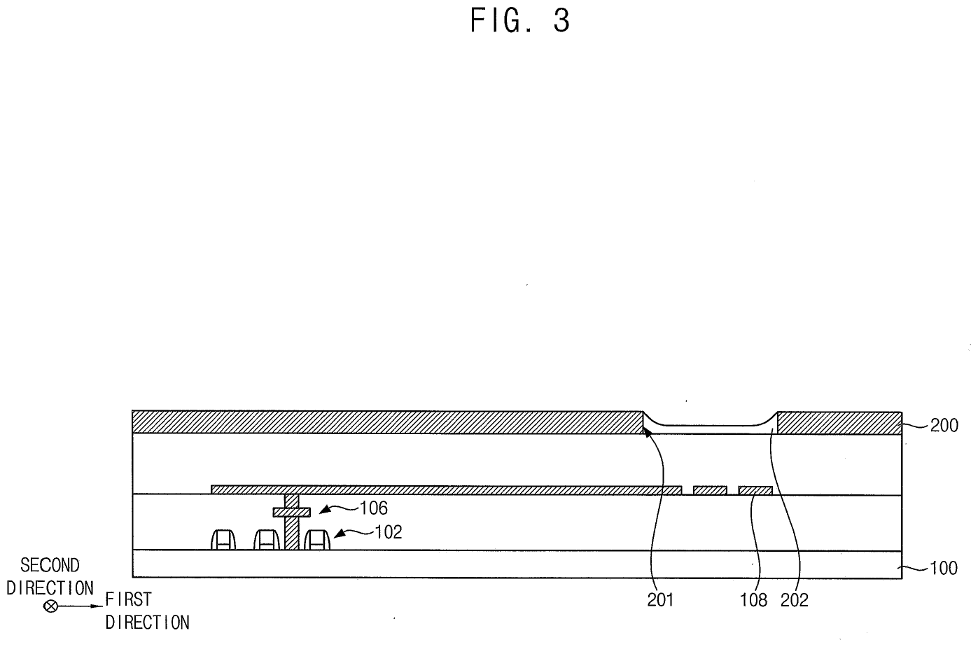

FIGS. 3 to 13 are cross-sectional views illustrating a method of manufacturing a vertical semiconductor device in accordance with example embodiments. Referring to FIG. 3, circuit patterns constituting a peripheral circuit may be formed on a substrate 100, and a first lower insulating interlayer 104 may be formed to cover the circuit patterns. The circuit patterns may include lower transistors 102 and lower wiring 106. The lower wiring 106 may include lower contact plugs and lower conductive patterns.

A lower pad pattern 108 may be formed on the first lower insulating interlayer 104. A second lower insulating interlayer 110 may be formed on the first lower insulating interlayer 104 and the lower pad pattern 108. An upper surface of the second lower insulating interlayer 110 may be substantially flat.

A base semiconductor layer may be formed on the second lower insulating interlayer 110, and the base semiconductor layer may be patterned to form base semiconductor patterns 200. The base semiconductor layer may include polysilicon. A first opening 201 may be formed between the base semiconductor patterns 200.

In example embodiments, the base semiconductor pattern 200 may be disposed to face in the vertical direction a portion for forming a cell stack structure. The first opening 201 may be disposed to face in the vertical direction a portion for forming a through via contact. In example embodiments, the first opening 201 may be formed at outside the cell stack structure 260. The first opening 201 may have a width of about 5 μm to about 200 μm in the first direction.

A lower filling insulation layer may be formed on the base semiconductor pattern 200 to fill the first opening 201. The lower filling insulation layer may include silicon oxide. For example, the lower filling insulation layer may include a TEOS layer or an HDP oxide layer. The lower filling insulation layer may be planarized until an upper surface of the base semiconductor pattern 200 may be exposed to form a lower filling pattern 202 in the first opening 201. The planarization process may include a chemical mechanical polishing (CMP) process, for example.

In this case, the first opening 201 may have a wide width of about 5 μm to about 200 μm, so that a center portion of the lower filling pattern 202 may be further polished during the planarization process. Thus, an upper surface of the lower filling pattern 202 may not be flat, and the upper surface of the lower filling pattern 202 may include a dishing portion in which the center portion of the upper surface may be recessed. The lower filling pattern 202 may not completely fill the first opening 201 due to the dishing portion.

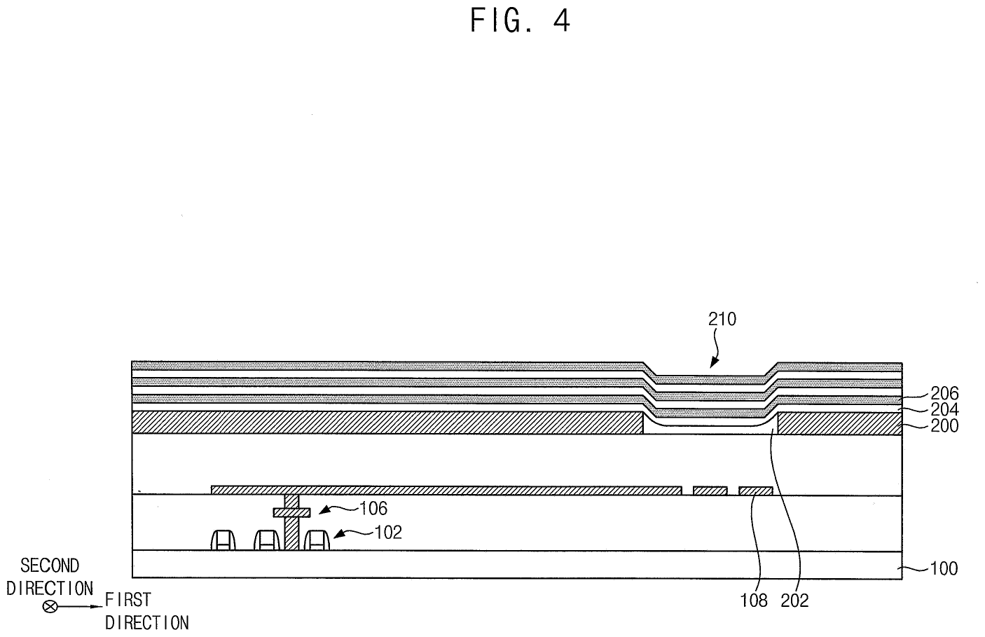

Referring to FIG. 4, first insulation layers 204 and first sacrificial layers 206 may be alternately and repeatedly stacked on the base semiconductor pattern 200 and the lower filling pattern 202. The first insulation layer 204 may include silicon oxide. The first sacrificial layer 206 may include a material having an etching selectivity with respect to the first insulation layer 204. For example, the first sacrificial layer 206 may include a nitride such as silicon nitride.

The first sacrificial layer 206 may serve as a sacrificial layer for forming gates of a ground selection transistor and transistors below the ground selection transistor included in one of cell strings in the vertical semiconductor device. Therefore, the number of stacked first sacrificial layers 206 may be same as the number of the ground selection transistors and transistors below the ground selection transistors. In addition, an uppermost first sacrificial layer 206 may be transformed to a gate of the ground selection transistor by performing subsequent processes.

In example embodiments, the first sacrificial layers 206 may be formed as a gate of a ground selection transistor and a gate of two GIDL transistors. In this case, the first sacrificial layers 206 may be three stacked layers. In other example embodiments, the uppermost first sacrificial layer 206 may serve as a polishing stopper in a subsequent planarization process. In this case, although not shown, a thickness of the uppermost first sacrificial layer 206 may be greater than a thickness of the target gate pattern, considering that the uppermost first sacrificial layer 206 is partially removed during the planarization process. For example, the thickness of the uppermost first sacrificial layer 206 may have about 10 Å to about 100 Å greater than the thickness of the target gate pattern.

Upper surfaces and lower surfaces of the first insulation layers 204 and the first sacrificial layers 206 formed on the base semiconductor pattern 200 may be substantially planar. However, the upper surface of the lower filling pattern 202 may include the dishing portion, and thus the first insulation layers 204 and the first sacrificial layers 206 formed on the lower filling pattern 202 may include dishing portions. That is, upper surfaces of the first insulation layers 204 and the first sacrificial layers 206 formed on the lower filling pattern 202 may be relatively low levels (i.e., a height of an upper surface), when compared with upper surfaces of the first insulation layers 204 and the first sacrificial layers 206 formed on different portions. Thus, an upper surface of the uppermost first sacrificial layer 206 facing the lower filling pattern 202 may include a dishing portion.

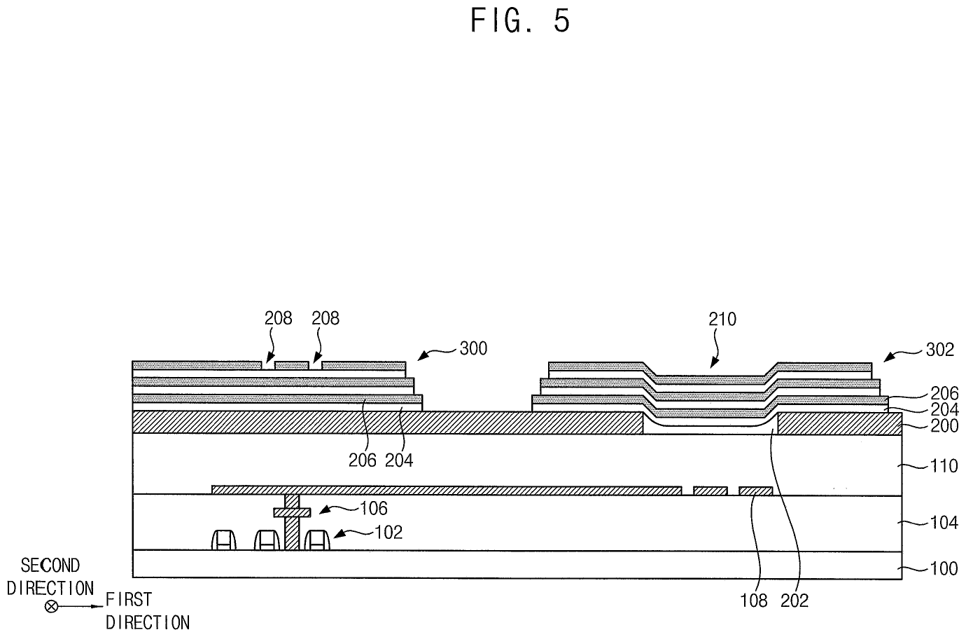

Referring to FIG. 5, the first sacrificial layers 206 and the first insulation layers 204 may be patterned to form a first cell mold structure 300 on the first region and a first dummy mold structure 302 on the second region. In addition, a portion of an uppermost first sacrificial layer 206 of the first cell mold structure 300 may be etched to form a ground line cutting region 208. This ground line cutting region 208 may be formed to have a width of about 0.5 μm to about 5 μm.

The first cell mold structure 300 may be formed on the base semiconductor pattern 200. Thus, upper surfaces and lower surfaces of the first sacrificial layers 206 and the first insulation layers 204 included in the first cell mold structure 300 may be substantially planar. The first cell mold structure 300 may extend in the first direction. Although not shown, the plurality of first cell mold structures 300 may be arranged in the second direction, and the first cell mold structures 300 may be spaced apart from each other in the second direction. Further, although not shown, the first cell mold structures 300 may be arranged in the first direction, and the first cell mold structures 300 may be spaced apart from each other in the first direction.

The first dummy mold structure 302 may be formed on the lower filling pattern 202 and the base semiconductor pattern 200. Thus, in the first dummy mold structure 302, dishing portions may be included on upper surfaces of the first sacrificial layers 206 and the first insulation layers 204 formed on the lower filling pattern 202. In addition, an edge portion of the first cell mold structure 300 in the first direction may have a stepped shape. Also, an edge portion of the first dummy mold structure 302 in the first direction may have a stepped shape.

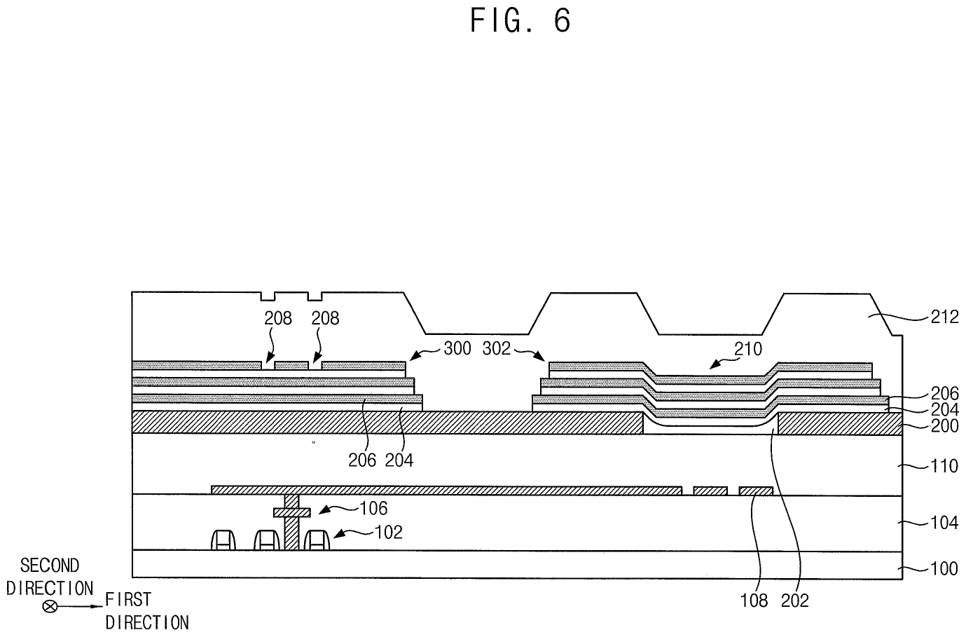

Referring to FIG. 6, a first lower insulation layer 212 may be formed on the first cell mold structure 300, the first dummy mold structure 302, and the base semiconductor pattern 200 therebetween. The first lower insulation layer 212 may be formed to completely cover the first cell mold structure 300 and the first dummy mold structure 302.

An upper surface of the first lower insulation layer 212 may not be flat due to a step difference between the upper surfaces of the first cell mold structure 300, the first dummy mold structure 302, and the base semiconductor pattern 200. For example, the first lower insulation layer 212 positioned on the base semiconductor pattern 200 may have a lowest upper surface. The upper surface of the first lower insulation layer 212 positioned on the base semiconductor pattern 200 may be higher than upper surfaces of the first cell mold structure 300 and the first dummy mold structure 302. The first lower insulation layer 212 may include silicon oxide.

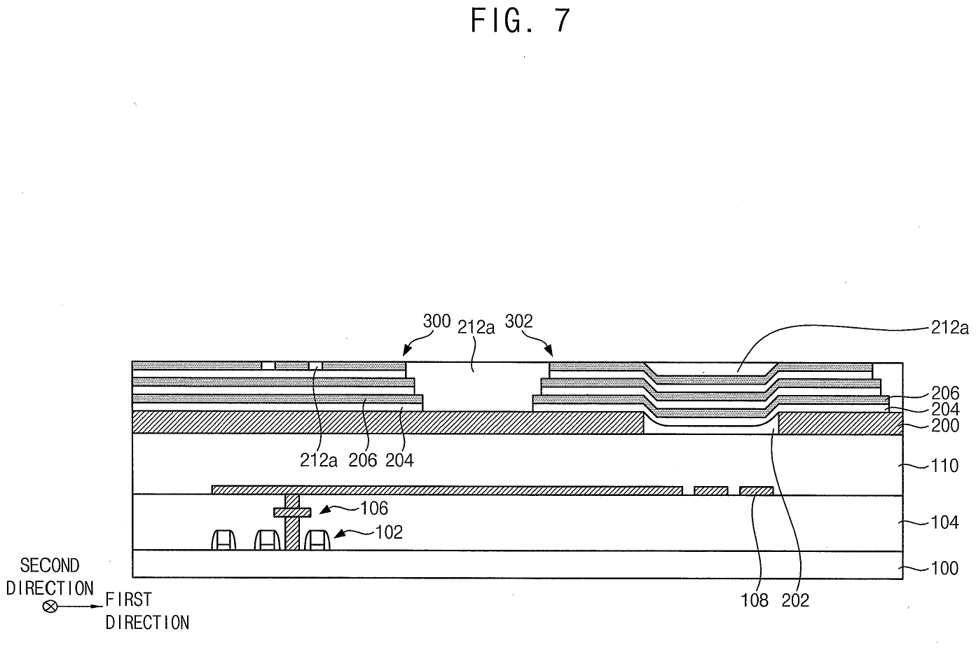

Referring to FIG. 7, the first lower insulation layer 212 may be planarized until an upper surface of an uppermost first sacrificial layer 206 may be exposed to form a first lower insulation pattern 212a. The planarization process may include a chemical mechanical polishing process, for example. The first lower insulation pattern 212a may be formed on the base semiconductor pattern 200, a portion of the ground line cutting region 208 of the first cell mold structure 300, and a dishing portion of an upper surface of the first dummy mold structure 302. The first lower insulation pattern 212a formed on the base semiconductor pattern 200 may fill a space between the first cell mold structure 300 and the first dummy mold structure 302. In addition, the first lower insulation pattern 212a may fill the ground line cutting region 208 of the first cell mold structure 300 and the dishing portion of the upper surface of the first dummy mold structure 302. Therefore, the upper surfaces of the first cell mold structure 300, the first dummy mold structure 302, and the first lower insulation pattern 212a may be substantially flat, and may be coplanar with each other.

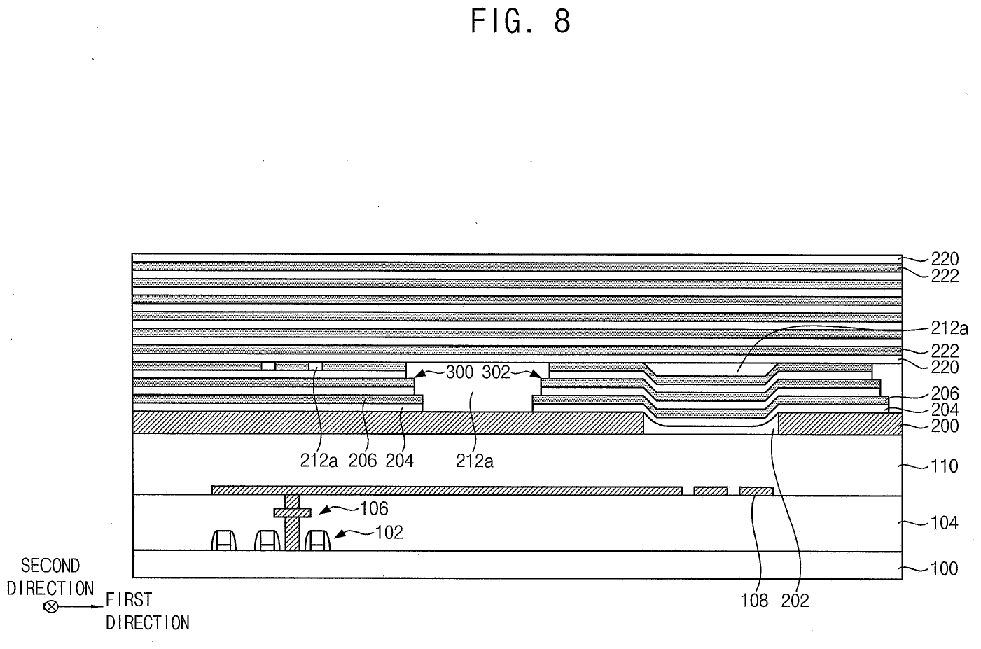

Referring to FIG. 8, second insulation layers 220 and second sacrificial layers 222 may be alternately and repeatedly stacked on the first cell mold structure 300, the first dummy mold structure 302, and the first lower insulation pattern 212a. The second insulation layer 220 may include silicon oxide. The second sacrificial layer 222 may include a material having an etch selectivity with respect to the second insulation layer 220. For example, the second sacrificial layer 222 may include a nitride such as silicon nitride. In example embodiments, the second insulation layer 220 may be disposed at a top portion of a stack structure including the second insulation layers 220 and the second sacrificial layers 222. An uppermost second insulation layer 220 may be partially removed in a subsequent polishing process. Thus, although not shown, the uppermost second insulation layer 220 may be formed to have a thickness greater than a thickness of one of other second insulation layers.

The second sacrificial layers 222 may serve as sacrificial layers for forming gates of cell transistors included in one of cell strings in the vertical semiconductor device.

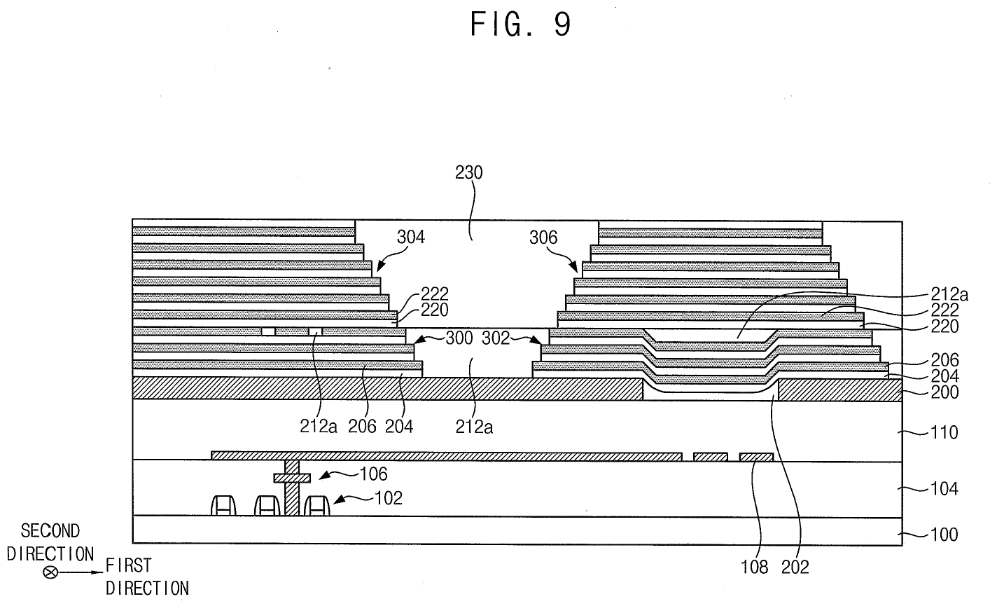

Referring to FIG. 9, the second sacrificial layers 222 and the second insulation layers 220 may be patterned to form a second cell mold structure 304 on the first cell mold structure 300 and a second dummy mold structure 306 on the first dummy mold structure 302. An edge portion of the second cell mold structure 304 in the first direction may have a stepped shape. In addition, an edge portion of the second dummy mold structure 306 in the first direction may have a stepped shape.

A second lower insulation layer may be formed on the second cell mold structure 304, the second dummy mold structure 306, and the first lower insulation pattern 212a therebetween. An upper surface of the second lower insulation layer may be planarized until upper surfaces of the second cell mold structure 304 and the second dummy mold structure 306 may be exposed to form a second lower insulation pattern on the first lower insulation pattern. The planarization process may include a chemical mechanical polishing process. The second lower insulation pattern 230 may cover sidewalls of the second cell mold structure 304 and the second dummy mold structure 306. By using the planarization process, the upper surfaces of the second cell mold structure 304, the second dummy mold structure 306, and the second lower insulation pattern 230 may be substantially flat, and may be coplanar with each other.

If the second dummy mold structure 306 is not formed, an insulating interlayer may be formed on a portion where the second dummy mold structure 306 is formed, instead of the second dummy mold structure 306. Therefore, a size of an upper surface of the insulating interlayers may be increased. In this case, when the planarization process is performed, a dishing defect may occur on the upper surface of the insulating interlayer. However, as the second dummy mold structure 306 is formed, a dishing defect of the upper surface of the second lower insulation pattern 230 may be decreased by using the planarization process.

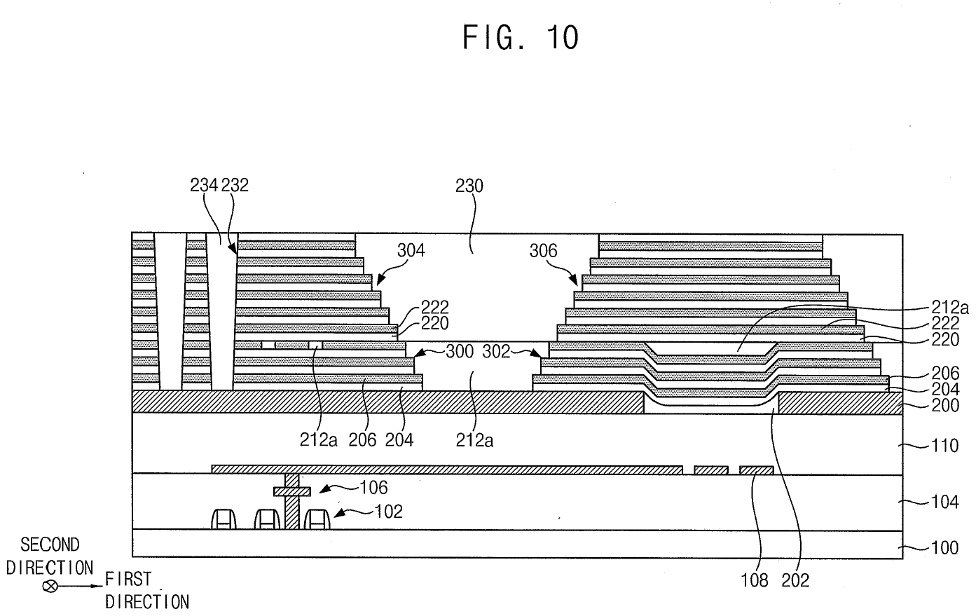

Referring to FIG. 10, the second cell mold structure 304 and the first cell mold structure 300 may be etched by a photolithography process. Thus, a lower channel hole 232 may be formed through the second cell mold structure 304 and the first cell mold structure 300. The lower channel hole 232 may expose an upper surface of the base semiconductor pattern 200. A filling sacrificial layer 234 may be formed to fill the lower channel hole 232.

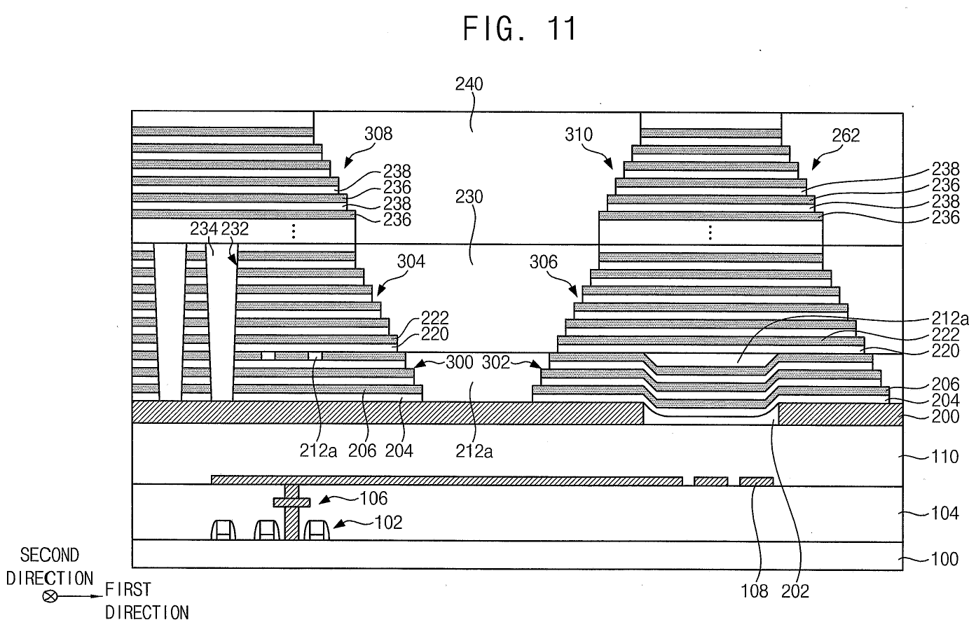

Referring to FIG. 11, third insulation layers and third sacrificial layers may be alternately and repeatedly stacked on the second cell mold structure 304, the second dummy mold structure 306, and the second lower insulation pattern 230. In these example embodiments, the third insulation layer may be disposed at a top portion of a stack structure including the third insulation layers and the third sacrificial layers. The third sacrificial layers may also serve as sacrificial layers for forming gates of cell transistors and gates of string selection transistors included in one of cell string in the vertical semiconductor device. The third sacrificial layers and the third insulation layers may be patterned to form a third cell mold structure 308 on the second cell mold structure 304 and a third dummy mold structure 310 on the second dummy mold structure 306. An edge portion of the third cell mold structure 308 in the first direction may have a stepped shape. In addition, an edge portion of the third dummy mold structure 310 in the first direction may have a stepped shape.

Therefore, a cell mold structure in which the first to third cell mold structures 300, 304, and 308 are stacked may be formed on the first region. A dummy mold structure 262 in which the first to third dummy mold structures 302, 306, and 310 are stacked may be formed on the second region. An edge portion of the cell mold structure in the first direction may have a stepped shape. In addition, an edge portion of the dummy mold structure 262 in the first direction may have a stepped shape.

A third lower insulation layer may be formed on the third cell mold structure 308, the third dummy mold structure 310, and the second lower insulation pattern 230 therebetween. An upper surface of the third lower insulation layer may be planarized until the upper surfaces of the third cell mold structure 308 and the third dummy mold structure 310 are exposed to form a third lower insulation pattern 240 on the second lower insulation pattern 230. The third lower insulation pattern 240 may cover sidewalls of the third cell mold structure 308 and the third dummy mold structure 310.

By performing the planarization process, upper surfaces of the third cell mold structure 308, the third dummy mold structure 310, and the third lower insulation pattern 240 may be substantially flat. The upper surfaces of the third cell mold structure 308, the third dummy mold structure 310, and the third lower insulation pattern 240 may be coplanar with each other. As the third dummy mold structure 310 is formed, a dishing defect of the upper surface of the third lower insulation pattern 240 may be decreased in the planarization process.

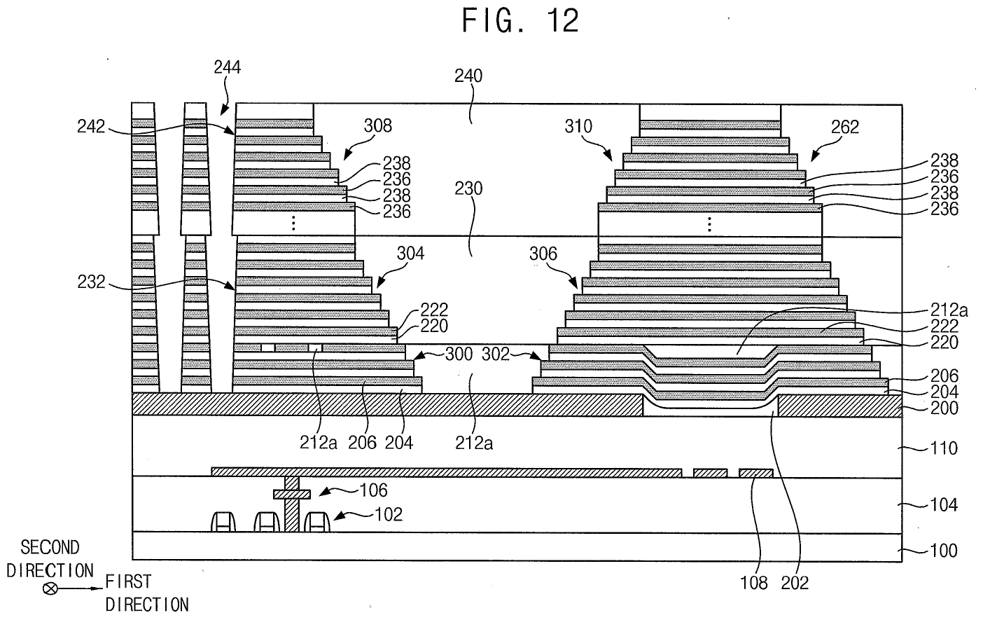

Referring to FIG. 12, the third cell mold structure 308 may be etched by a photolithography process to form an upper channel hole 242. The upper channel hole 242 may pass through the third cell mold structure 308 to expose an upper surface of the filling sacrificial layer 234 in the lower channel hole 232. In a photo process for forming the upper channel hole 242, a photo mask (e.g., reticle) may be aligned using an alignment mark (not shown) formed on the substrate 100. As the dishing defect may be decreased in the planarization process, removing of the alignment mark may be decreased in the planarization process. Therefore, failure in which the upper channel hole 242 is not formed at a target position due to remove the alignment mark may be decreased.

In example embodiments, preferably, center portions of the lower channel hole and upper channel hole 232 and 242 may be aligned in the vertical direction with each other. In some example embodiments, the lower and upper channel holes 232 and 242 may be communicate with each other, and the center portions of the lower and upper channel holes 232 and 242 may be mis-aligned in the vertical direction with each other. The filling sacrificial layer 234 may then be removed. Thus, a channel hole 244 in which the lower channel hole 232 and the upper channel hole 242 communicate with each other may be formed.

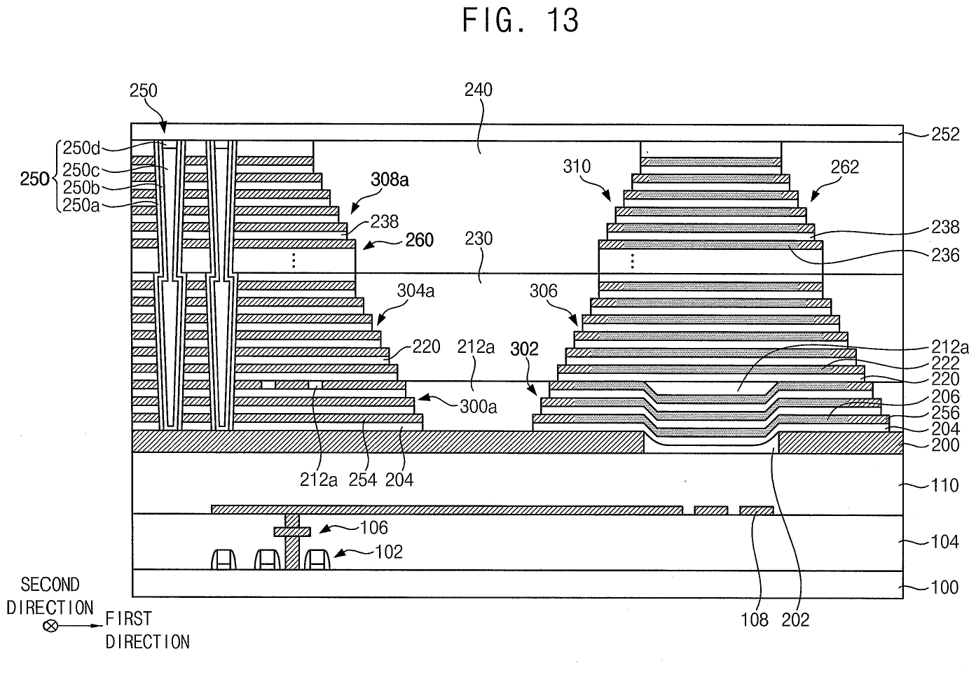

Referring to FIG. 13, a channel structure 250 may be formed in the channel hole 244. The channel structure 250 may include a charge storage structure 250a, a channel 250b, a filling insulation pattern 250c, and a capping pattern 250d. The charge storage structure 250a may include a blocking layer, a charge storage layer, and a tunnel insulation layer. The blocking layer, the charge storage layer, and the tunnel insulation layer may be sequentially stacked on a sidewall of the channel hole 244. The channel 250b may contact the tunnel insulation layer, and the channel 250b may be electrically connected to the base semiconductor pattern 200.

Thereafter, a first insulating interlayer 252 may be formed on the third cell mold structure 308, the channel structure 250, the third dummy mold structure 310, and the third lower insulation pattern 240. The first insulating interlayer 252 may include silicon oxide. The first to third sacrificial layers 206, 222, 236 in the cell mold structures may be removed to form gaps (not shown) between the first to third insulation layers 204, 220, 238 in the vertical direction.

In example embodiments, when the first to third sacrificial layers included in the cell mold structure are removed, the first to third sacrificial layers 206, 222, 236 included in the dummy mold structure 262 may be partially removed together to form gaps (not shown). For example, the first to third sacrificial layers 206, 222, and 236 positioned at an edge of the sidewall of the dummy mold structure 262 may be partially removed. And, in some alternative embodiments, when the first to third sacrificial layers included in the cell mold structure is removed, the first to third sacrificial layers 206, 222, 236 included in the dummy mold structure may not be removed. In this case, the dummy mold structure may not include the gaps.

A conductive material may fill in the gaps included in the cell mold structure to form gate patterns 254 in the gaps. The conductive material may include a barrier pattern and a metal pattern. Thus, the cell stack structure 260 in which the insulation layers 204, 220, 238 and the gate patterns 254 are alternately stacked may be formed. That is, the first to third sacrificial layers 206, 222, 236 included in the cell mold structure are replaced with the gate patterns 254, so that the cell stack structure 260 may be formed. The cell stack structure 260 may include a first cell stack structure 300a, a second cell stack structure 304a, and a third cell stack structure 308a stacked.

If gaps are included in the dummy mold structure 262, a conductive material may also fill in the gaps in the dummy mold structure 262. Thus, conductive patterns 256 may be formed in the gaps. The conductive material may be the same material as the gate pattern. The conductive patterns 256 may be formed at an edge portion of the dummy mold structure 262. If a gap is not formed in the dummy mold structure, as shown in FIG. 2, a conductive pattern may not be formed in the dummy mold structure.

Referring to FIG. 1 again, cell contact plugs 270 may be formed through the first insulating interlayer 252 and the lower insulation patterns. The cell contact plugs 270 may contact upper surfaces of the gate patterns 254 at the edge of the cell stack structure 260, respectively. Further, a through via contact 272 may be formed through the dummy mold structure 262, the lower filling pattern 202, and the second lower insulating interlayer 110. The through via contact 272 may contact the lower pad pattern 108. The through via contact 272 may pass through an inner portion of the first opening 201 between the base semiconductor patterns 200. Therefore, the through via contact 272 may pass through a portion of the dummy mold structure 262 facing the first opening 201 in the vertical direction. Therefore, the through via contact 272 may pass through the dishing portion of the first sacrificial layer 206 in the first dummy mold structure 302.

In example embodiments, one or more through via contacts 272 may be formed in the dummy mold structure 262. One or more through via contacts 272 may be disposed in the first opening 201. And, in other example embodiments, the conductive patterns 256 in the dummy mold structure 262 may not contact the through via contact 272. The conductive patterns 256 in the dummy mold structure 262 may be spaced apart from the through via contact 272.

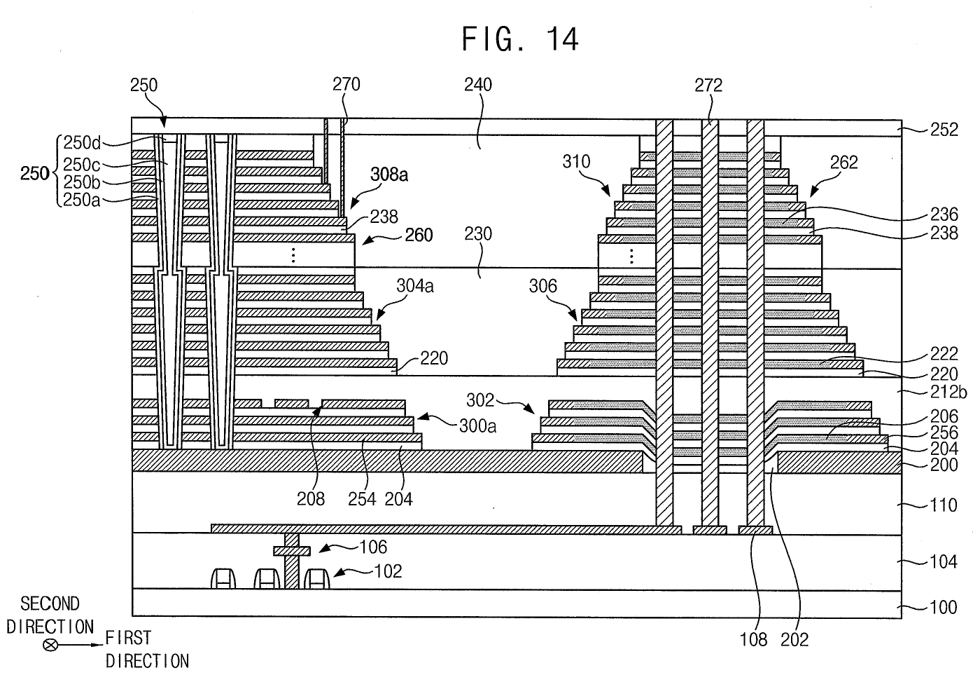

FIG. 14 is a cross-sectional view of a semiconductor device in accordance with example embodiments. The semiconductor device may be substantially the same as the semiconductor device illustrated with reference to FIG. 1, except for the lower insulation layer on the first cell stack structure and the first dummy mold structure. Therefore, redundant descriptions may be omitted or only briefly described. Referring to FIG. 14, a cell stack structure 260 may be formed on the base semiconductor pattern 200 in the first region, and a dummy mold structure may be formed on the base semiconductor pattern 200 and the lower filling pattern 202 in the second region 262.

The cell stack structure 260 may include a first cell stack structure 300a, a second cell stack structure 304a, and a third cell stack structure 308a sequentially stacked. The dummy mold structure 262 may include a first dummy mold structure 302, a second dummy mold structure 306, and a third dummy mold structure 310 sequentially stacked. The first cell stack structure 300a may be substantially the same as the first cell stack structure illustrated with reference to FIG. 1, and the first dummy mold structure 302 may be substantially the same as the first dummy mold structure illustrated with reference to FIG. 1.

A first lower insulation layer 212b may be formed on the first cell stack structure 300a, the first dummy mold structure 302 and the base semiconductor pattern 200. An upper surface of the first lower insulation layer 212b may be substantially flat. The first lower insulation layer 212b may include silicon oxide.

The first lower insulation layer 212b may fill a space between the first cell stack structure 300a and the first dummy mold structure 302 on the base semiconductor pattern 200. The first lower insulation layer 212b may cover the upper surface of the first dummy mold structure 302 to fill a dishing portion of the upper surface of the first dummy mold structure 302 facing the lower filling pattern 202. The first lower insulation layer 212b may cover an upper surface of the first cell stack structure 300a to fill the ground line cutting region 208.

As described above, the first lower insulation layer 212b may cover upper surfaces of the first cell stack structure 300a and the first dummy mold structure 302. The second cell stack structure 304a may be formed on the first lower insulation layer 212b. The second cell stack structure 304a may face the first cell stack structure 300a in the vertical direction. That is, a first lower insulation layer 212b may be formed between the first and second cell stack structures 300a and 304a in the vertical direction.

The second dummy mold structure 306 may be formed on the first lower insulation layer 212b. The second dummy mold structure 306 may face the first dummy mold structure 302 in the vertical direction. That is, the first lower insulation layer 212b may be formed between the first and second dummy mold structures 302 and 306. An upper surface of the first lower insulation layer 212b may be substantially planar, so that upper and lower surfaces of the second insulation layer 220 and the second sacrificial layer 222 included in the second dummy mold structure 306 may be substantially flat. Thus, a dishing defect may not occur on the upper surface of the second dummy mold structure 306 facing the lower filling pattern 202.

A second lower insulation pattern 230 may be formed on the first lower insulation layer 212b to fill a space between the second cell stack structure 304a and the second dummy mold structure 306. The second lower insulation pattern 230 may cover sidewalls of the second cell stack structure 304a and the second dummy mold structure 306. The second lower insulation pattern 230 may include silicon oxide. A structure substantially the same as that illustrated with reference to FIG. 1 may be formed on the second cell stack structure 304a, the second dummy mold structure, and the second lower insulation pattern 230.

As described above, the first lower insulation layer 212b may fill a dishing portion of the first sacrificial layer 206 in the first dummy mold structure 302, and an upper surface of the first lower insulation layer 212b may be substantially planar. Therefore, upper and lower surfaces of the second and third sacrificial layers 222 and 236 included in the second and third dummy mold structures 306 and 310 formed on the first lower insulation layer 212b may be substantially flat. Defects (e.g., instabilities in the dummy mold structure and process failures in the semiconductor device) that may occur due to uneven upper and lower surfaces of the second and third sacrificial layers 222 and 236 included in the second and third dummy mold structures 306 and 310 may be decreased. A dishing defect of the upper surface of the third lower insulation pattern 240 may be prevented by using the dummy mold structure 262, as described herein. Further, standby currents and leakage currents generated in the circuit patterns may be decreased by using the dummy mold structure 262.

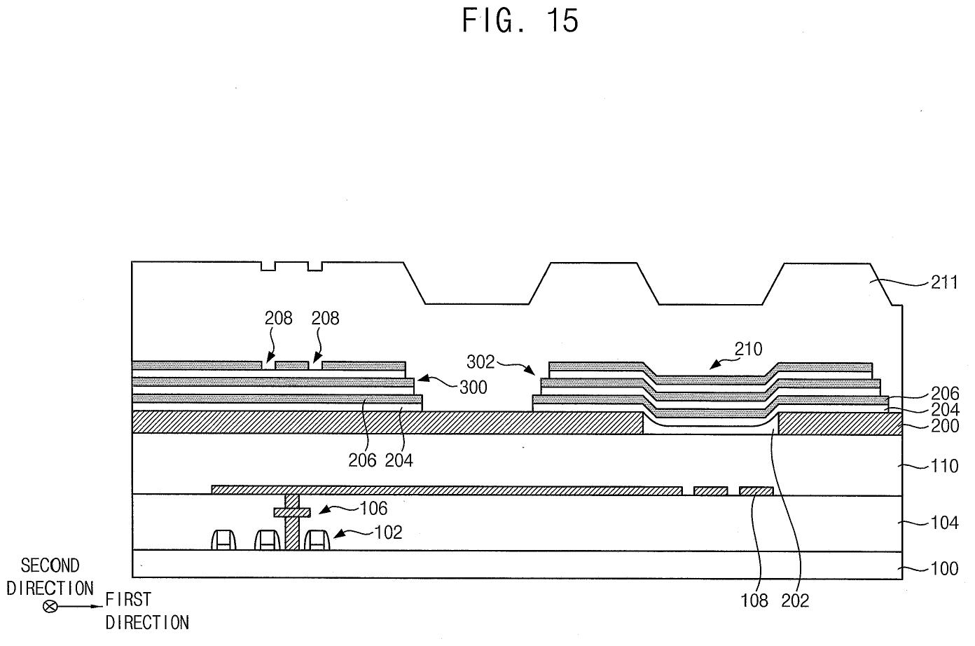

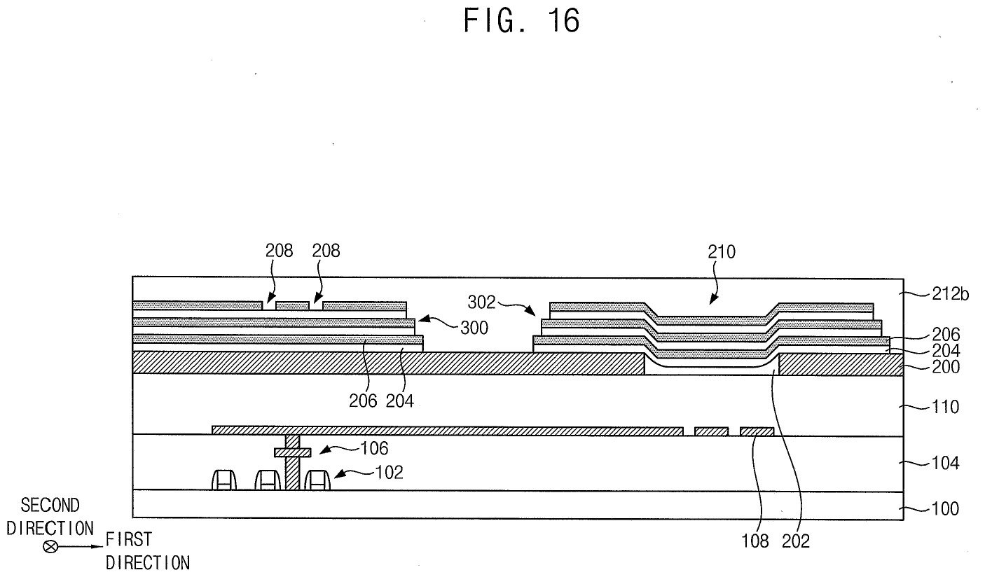

FIGS. 15 and 16 are cross-sectional views illustrating a method of manufacturing a vertical semiconductor device in accordance with example embodiments. Referring to FIG. 15, first, processes illustrated with reference to FIGS. 3 to 5 may be performed. Thereafter, a preliminary first lower insulation layer 211 may be formed on the first cell mold structure 300, the first dummy mold structure 302, and the base semiconductor pattern 200 therebetween. The preliminary first lower insulation layer 211 may include silicon oxide.

An upper surface of the preliminary first lower insulation layer 211 may not be flat due to a step difference between the upper surfaces of the first cell mold structure 300, the first dummy mold structure 302, and the base semiconductor pattern 200. The preliminary first lower insulation layer 211 formed on the base semiconductor pattern 200 may have a lowest upper surface.

The preliminary first lower insulation layer 211 may have a sufficient height so that the first lower insulation layer may remain on the first cell mold structure 300 and the first dummy mold structure 302 after performing a subsequent planarization process. An upper surface of the preliminary first lower insulation layer 211 formed on the base semiconductor pattern 200 may be higher than an upper surface of the lower insulation layer remained on the first cell mold structure 300 and the first dummy mold structure 302 after the planarization process.

Referring to FIG. 16, an upper surface of the preliminary first lower insulation layer 211 may be planarized to form a first lower insulation layer 212b having a flat upper surface. The planarization process may include a chemical mechanical polishing process. The first lower insulation layer 212b may fill a space between the first cell stack structure 300a and the first dummy mold structure 302 on the base semiconductor pattern 200. The first lower insulation layer 212b may cover the upper surface of the first dummy mold structure 302 to fill a dishing portion of the first dummy mold structure 302 facing the lower filling pattern 202. The first lower insulation layer 212b may cover an upper surface of the first cell stack structure 300a to fill the ground line cutting region 208. The first lower insulation layer 212b may cover upper surfaces of the first cell stack structure 300a and the first dummy mold structure 302. In example embodiments, a thickness of the first lower insulation layer 212b may be greater than a thickness of each of the first insulation layers 204 included in the first cell mold structure 300 and the first dummy mold structure 302. Thereafter, the processes illustrated with reference to FIGS. 8 to 13 and 1 may be performed on the first lower insulation layer 212b. Thus, the vertical semiconductor device as shown in FIG. 14 may be manufactured.

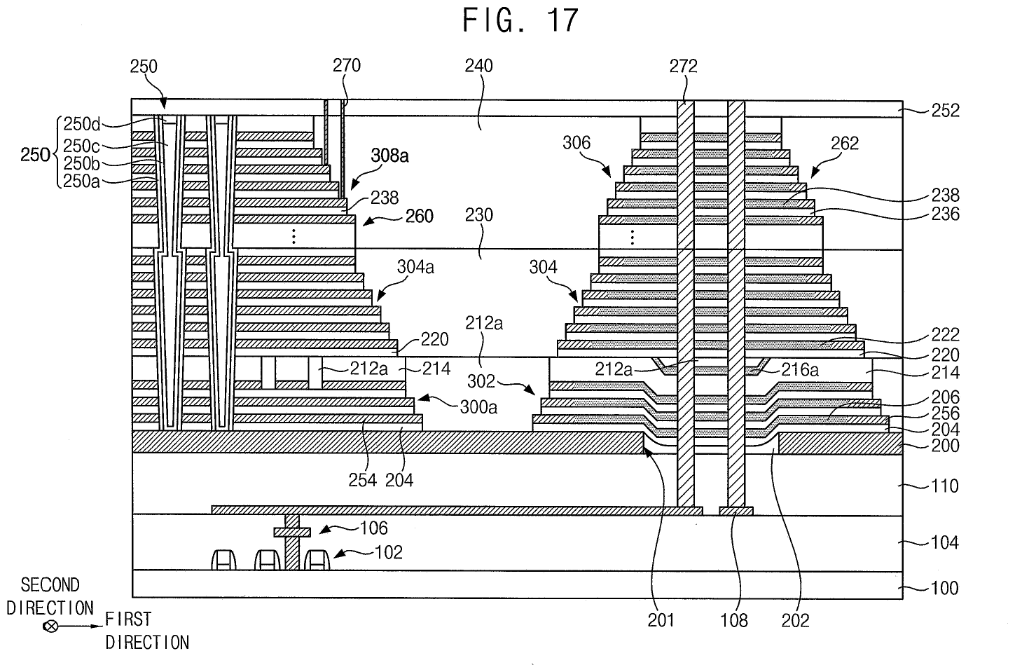

FIG. 17 is a cross-sectional view of a semiconductor device in accordance with example embodiments. The semiconductor device may be substantially the same as the semiconductor device described with reference to FIG. 1, except for an upper portion of the first dummy mold structure. Therefore, redundant descriptions may be omitted or only briefly described. Referring to FIG. 17, a cell stack structure 260 may be formed on the base semiconductor pattern 200 in the first region, and a dummy mold structure may be formed on the base semiconductor pattern 200 and the lower filling pattern 202 in the second region. The cell stack structure 260 may have a first cell stack structure 300a, a second cell stack structure 304a, and a third cell stack structure 308a sequentially stacked. The dummy mold structure 262 may have a first dummy mold structure 302, a second dummy mold structure 306, and a third dummy mold structure 310 sequentially stacked.

The first cell stack structure 300a may have a structure in which a first insulation layer 204 and a gate pattern 254 are alternately and repeatedly stacked. The first cell stack structure 300a may extend in a first direction, and an edge portion of the first cell stack structure 300a in the first direction may have a stepped shape. An upper insulation layer 214 may be formed on an uppermost portion of the first cell stack structure 300a. The upper insulation layer 214 may be formed on an uppermost gate pattern 254 of the first cell stack structure. The upper insulation layer 214 may include silicon oxide. In example embodiments, a thickness of the upper insulation layer 214 may be greater than a thickness of the first insulation layer 204.

The first dummy mold structure 302 may have a structure in which a first insulation layer 204 and a first sacrificial layer 206 may be alternately and repeatedly stacked. The first dummy mold structure 302 may be formed on the base semiconductor pattern 200 and the lower filling pattern 202 in the second region. An upper surface of the lower filling pattern 202 may be lower than the upper surface of the base semiconductor pattern 200. Therefore, upper and lower surfaces of the first insulation layer 204 and the first sacrificial layer 206 included in the first dummy mold structure 302 may not be planar. That is, in the first dummy mold structure 302, upper and lower surfaces of the first insulation layer 204 and the first sacrificial layer 206 formed on the base semiconductor pattern 200 may be higher than upper and lower surfaces of the first insulation layer 204 and the first sacrificial layer 206 formed on the lower filling pattern 202.

The upper insulation layer 214 may be formed on an uppermost portion of the first dummy mold structure 302. The upper insulation layer 214 may be formed on an uppermost first sacrificial layer 206 in the first dummy mold structure 302. A center portion of an upper surface of the upper insulation layer 214 facing the lower filling pattern 202 may include a recess. That is, the upper surface of the upper insulation layer 214 may include a dishing portion. A residual stopping layer pattern 216a may be conformally formed on a surface of the recess of the upper insulation layer 214. That is, the residual stopping layer pattern 216a may be disposed on the first dummy mold structure 302 to face the first opening 201. An upper surface and a lower surface of the residual stopping layer pattern 216a may not be planar. For example, the residual stopping layer pattern 216a may have an uneven upper surface and an uneven lower surface. The residual stopping layer pattern 216a may include silicon nitride.

A first lower insulation pattern 212a may be formed on the base semiconductor pattern 200 to fill a space between the first cell stack structure 300a and the first dummy mold structure 302. The first lower insulation pattern 212a may cover sidewalls of the first cell stack structure 300a and of the first dummy mold structure 302. The first lower insulation pattern 212a may include silicon oxide. The first lower insulation pattern 212a may be formed on the residual stopping layer pattern 216a, and may fill a dishing portion of an upper surface of the first dummy mold structure 302. Further, the first lower insulation pattern 212a may fill the ground line cutting region 208.

Therefore, upper surfaces of the first cell stack structure 300a, the first dummy mold structure 302, and the first lower insulation pattern 212a may be substantially planar. Upper surfaces of the first cell stack structure 300a, the first dummy mold structure 302, and the first lower insulation pattern 212a may be coplanar with each other.

A structure substantially the same as that illustrated with reference to FIG. 1 may be formed on the upper surface of the upper insulation layer 214 and the first lower insulation pattern 212a. In addition, as upper surfaces of the upper insulation layer 214 and the first lower insulation pattern 212a are substantially flat, upper and lower surfaces of the second and third sacrificial layers 222 and 236 in the second and third dummy mold structures 306 and 310 may be substantially flat. Thus, defects (e.g., instabilities in the dummy mold structure and process failures of the semiconductor device) that may occur due to uneven second and third sacrificial layers 222 and 236 in the second and third dummy mold structures 306 and 310 may be decreased.

A stopper layer pattern may be used in the process of forming the first cell stack structure 300a and the first dummy mold structure 302, so that the gate pattern in the cell stack structure 260 may be formed to have a uniform thickness. Further, a dishing defect of the upper surface of the third lower insulation pattern 240 may be prevented by the dummy mold structure 262. In addition, standby currents and leakage currents generated in the circuit pattern may be decreased by the dummy mold structure 262.

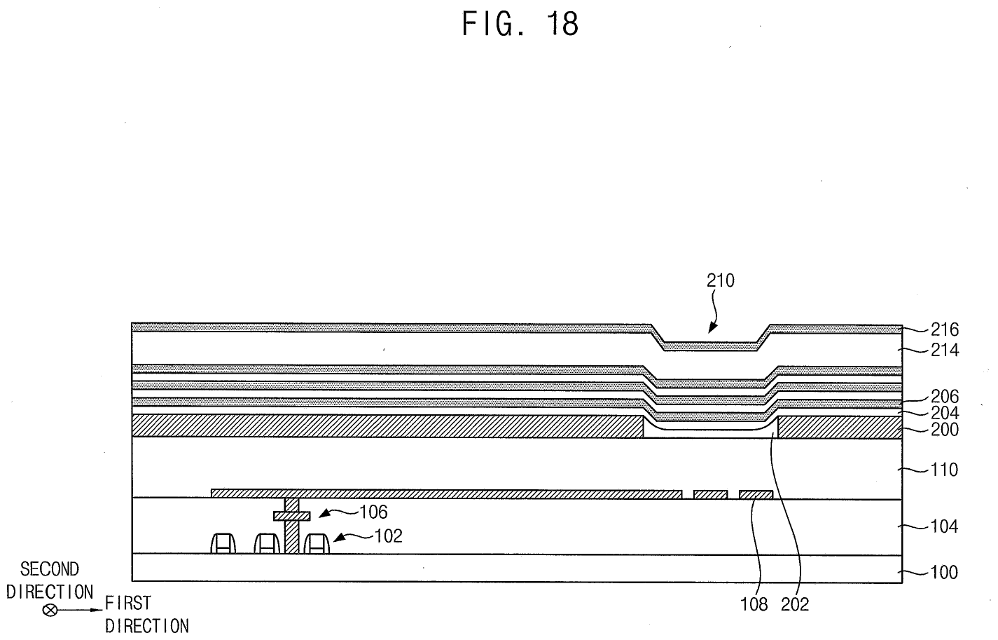

FIGS. 18 to 22 are cross-sectional views illustrating a method of manufacturing a vertical semiconductor device in accordance with example embodiments. Referring to FIG. 18, first, processes illustrated with reference to FIGS. 3 and 4 may be performed.

An upper insulation layer 214 may be formed on an uppermost first sacrificial layer 206. In example embodiments, the upper insulation layer 214 may be formed to have a thickness greater than a thickness of the first insulation layer 204. A stopping layer 216 may be formed on the upper insulation layer 214. The upper insulation layer 214 may include silicon oxide. The stopping layer 216 may include silicon nitride. Upper surfaces of the upper insulation layer 214 and the stopping layer 216 facing the lower filling pattern 202 may have a relatively low height, and thus an upper surface of the stopping layer 216 may include a dishing portion.

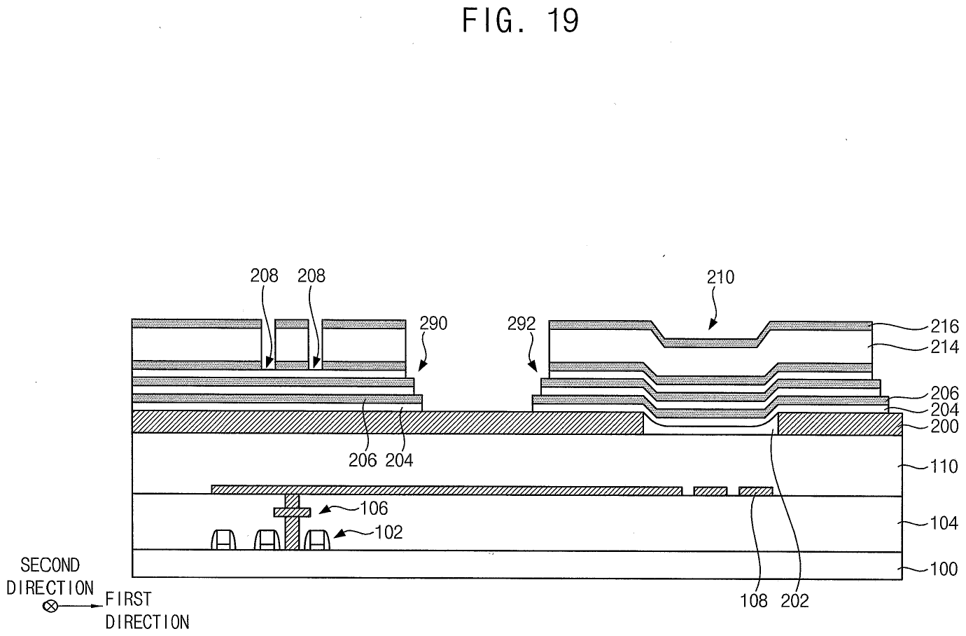

Referring to FIG. 19, the stopping layer 216, the upper insulation layer 214, the first sacrificial layers 206, and the first insulation layers 204 may be patterned to form a preliminary first cell mold structure on the first region and a preliminary first dummy mold structure 292 on the second region. Further, in the preliminary first cell mold structure, the stopping layer 216, the upper insulation layer 214, and an uppermost first sacrificial layer 206 may be partially etched to form a ground line cutting region 208.

The preliminary first cell mold structure 290 may be formed on the base semiconductor pattern 200. Thus, upper and lower surfaces of the first sacrificial layers 206 and the first insulation layers 204 included in the preliminary first cell mold structure 290 may be substantially flat. The preliminary first dummy mold structure 292 may be formed on the lower filling patterns 202 and the base semiconductor pattern 200. Thus, in the preliminary first dummy mold structure 292, surfaces of the first sacrificial layers 206, the first insulation layers 204, the upper insulation layer 214a, and the stopping layer 216 formed on the lower filling pattern 202 may include dishing portions. An edge portion of the preliminary first cell mold structure 290 in the first direction may have a stepped shape. In addition, an edge portion of the preliminary first dummy mold structure 292 in the first direction may have a stepped shape.

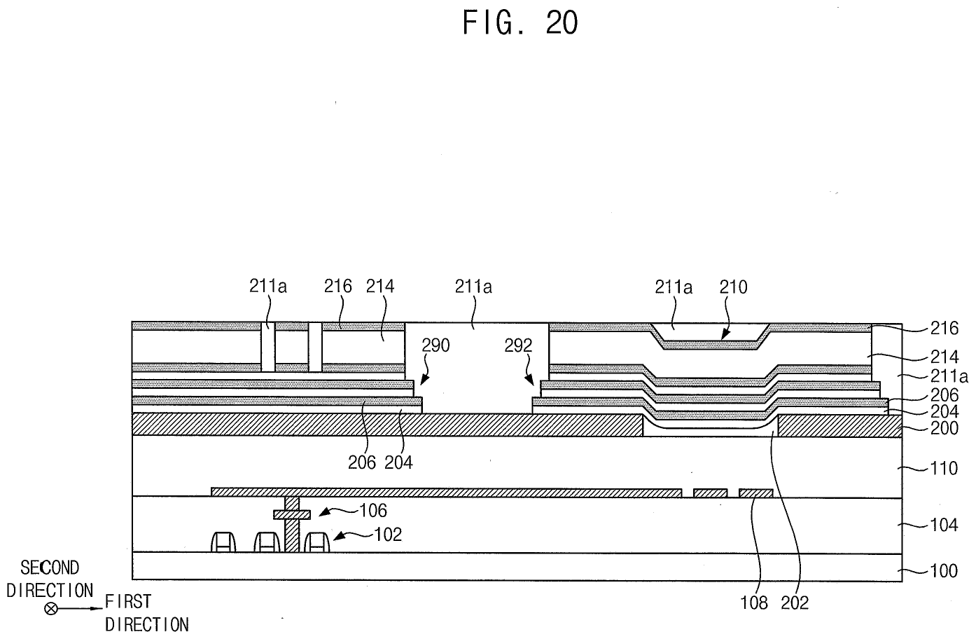

Referring to FIG. 20, a first lower insulation layer may be formed on the preliminary first cell mold structure 290, the preliminary first dummy mold structure 292, and the base semiconductor pattern 200 therebetween. The first lower insulation layer may be formed to completely cover the preliminary first cell mold structure 290 and the preliminary first dummy mold structure 292. An upper surface of the first lower insulation layer on the base semiconductor pattern 200 may be higher than upper surfaces of the preliminary first cell mold structure 290 and the preliminary first dummy mold structure 292. The first lower insulation layer may include silicon oxide.

Thereafter, an upper surface of the first lower insulation layer may be planarized until the upper surface of the stopping layer 216 may be exposed to form a preliminary first lower insulation pattern 211a. The planarization process may include a chemical mechanical polishing process. When the stopping layer 216 is exposed, a polishing process may be stopped. The first sacrificial layer 206 may not be exposed in the polishing process by the stopping layer 216. Thus, damage of the first sacrificial layer 206 in the polishing process may be prevented. The first sacrificial layer 206 may be replaced with a gate pattern by a subsequent process, so that a thickness of the gate pattern may be uniform. In the planarization process, the stopping layer facing the lower filling pattern 202 may not be exposed.

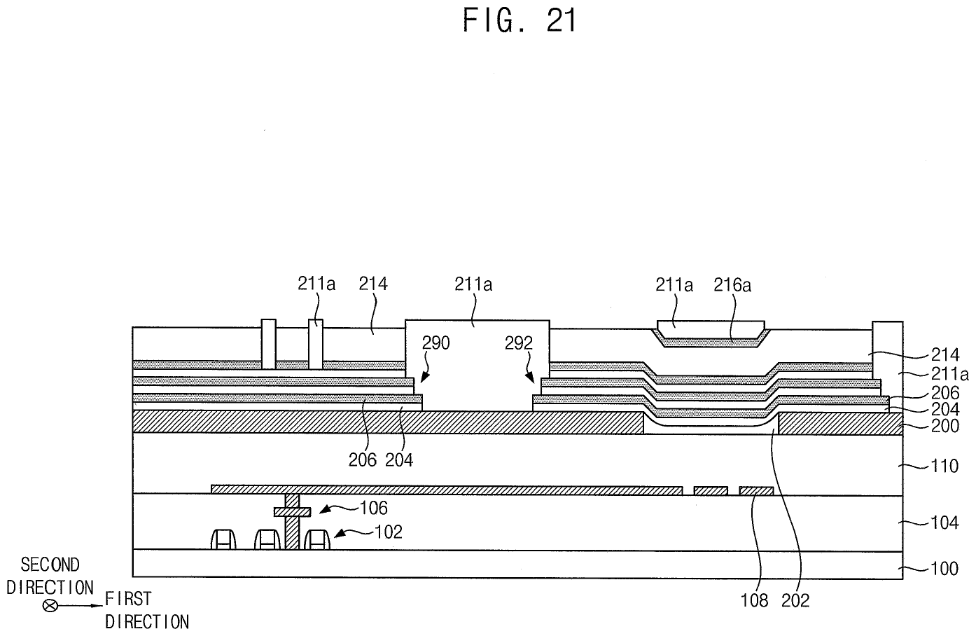

Referring to FIG. 21, the stopping layer 216 may be removed. In the removing process, the stopping layer facing the lower filling pattern 202 may not be etched to form a residual stopping layer pattern 216a. In example embodiments, the removing process of the stopping layer 216 may be performed by a wet etching process.

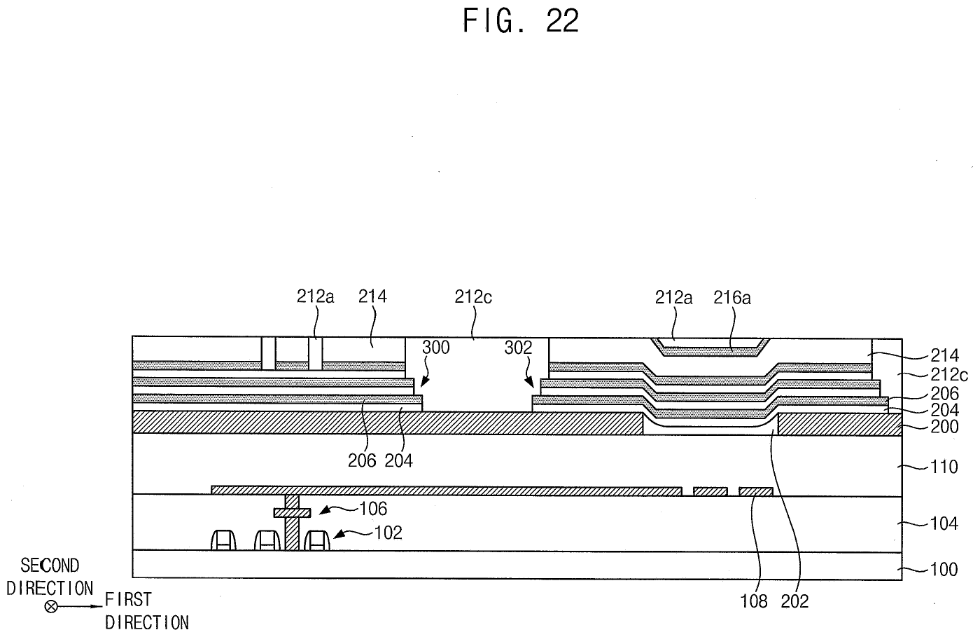

Referring to FIG. 22, upper surfaces of the preliminary first cell mold structure 290, the preliminary first dummy mold structure 292, and the preliminary first lower insulation pattern 211a may be planarized to form a first cell mold structure 300, a first dummy mold structure 302 and a first lower insulation pattern 212a. The planarization process may include a chemical mechanical polishing process.

Upper surfaces of the upper insulation layer 214 and the preliminary first lower insulation pattern 211a in the preliminary first cell mold structure 290 may be planarized to form the first cell mold structure 300 having a flat upper surface. The preliminary first lower insulation pattern 211a between the preliminary first cell mold structure 290 and the preliminary first dummy mold structures 292 may be planarized to form the first lower insulation pattern 212a. Upper surfaces of the upper insulation layer 214 and the preliminary first lower insulation pattern 211a in the preliminary first dummy mold structure 292 may be planarized to form the first dummy mold structure 302 having a flat upper surface. The first lower insulation pattern 212a may be formed on the base semiconductor pattern 200, the ground line cutting region 208 of the first cell mold structure 300, and a residual stopping layer pattern 216a of the first dummy mold structure 302.

Upper surfaces of the first cell mold structure 300, the first dummy mold structure 302, and the first lower insulation pattern 212a may be substantially flat. Upper surfaces of the first cell mold structure 300, the first dummy mold structure 302, and the first lower insulation pattern 212a may be coplanar with each other. Thereafter, the processes illustrated with reference to FIGS. 8 to 13 and 1 may be performed. Thus, the vertical semiconductor device as shown in FIG. 17 may be manufactured.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1. An integrated circuit device, comprising:
a plurality of circuit patterns on a substrate;
a lower insulating interlayer on the circuit patterns;
base semiconductor patterns on the lower insulating interlayer, said base semiconductor patterns including first and second base semiconductor patterns, which are spaced apart from each other by an opening extending therebetween;
a memory cell stack structure on at least one of the base semiconductor patterns; and
a dummy mold structure, which is: (i) spaced apart from the memory cell stack structure, (ii) extends on the first and second base semiconductor patterns, and (iii) extends into the opening, said dummy mold structure comprising:
a first dummy mold structure comprising a plurality of first insulation layers and the first sacrificial layers, which are alternately stacked, said first insulation layers and said first sacrificial layers having nonplanar upper and lower surfaces, which have a dish-shaped cross-section;
a first lower insulation pattern filling a dish-shaped recess in an upper surface of the first dummy mold structure; and
an upper dummy mold structure on the first dummy mold structure and the first lower insulation pattern, said upper dummy mold structure including second insulation layers and second sacrificial layers, which are alternately stacked, and have substantially flat upper and lower surfaces.

2. The device of claim 1, wherein the memory cell stack structure comprises:
a first memory cell stack structure including first insulation layers and gate patterns, which are alternately stacked and have upper and lower surfaces that are substantially planar; and
an upper memory cell stack structure on the first memory cell stack structure, the upper memory cell stack structure including second insulation layers and gate patterns, which are alternately stacked and have upper and lower surfaces that are substantially planar.

3. The device of claim 2, wherein the second sacrificial layers in the upper dummy mold structure and the gate patterns in the upper memory cell stack structure are positioned at the same level in a vertical direction, respectively.

4. The device of claim 2, wherein an uppermost gate pattern in the first memory cell stack structure functions as a gate pattern of a ground selection transistor.

5. The device of claim 4, wherein the uppermost gate pattern in the first memory cell stack structure includes a ground line cutting region, which is a portion cut off from the uppermost gate pattern; and wherein the first lower insulation pattern fills the ground line cutting region.

6. The device of claim 2, wherein a portion of the first lower insulation pattern is formed on a portion of the base semiconductor pattern that extends between the first memory cell stack structure and the first dummy mold structure, and fills a space between the first memory cell stack structure and the first dummy mold structure; and wherein the upper surfaces of the first memory cell stack structure, the first dummy mold structure, and the first lower insulation pattern are substantially coplanar with each other.

7. The device of claim 2, further comprising a residual stopping layer pattern on an upper portion of the first dummy mold structure, which faces the first opening.

8. The device of claim 8, wherein upper surfaces and lower surfaces of the residual stopping layer pattern are not planar.

9. The device of claim 1, further comprising a channel structure in a channel hole passing through the memory cell stack structure; and wherein the channel structure includes a channel electrically connected to the base semiconductor patterns.

10. The device of claim 9, wherein the channel hole includes a lower channel hole positioned at a lower portion of the memory cell stack structure, and an upper channel hole, which is positioned at an upper portion of the memory cell stack structure and communicates with the lower channel hole.

11. The device of claim 1, further comprising a lower filling pattern in the first opening; and wherein a center portion of the upper surface of the lower filling pattern has a dish-shaped cross section.

12. The device of claim 1, wherein the first opening has a width of about 5 μm to about 200 μm.

13. The device of claim 1, further comprising a through via contact electrically connected to the circuit patterns; and wherein the through via contact passes through a portion of the dummy mold structure facing the first opening.

14. The device of claim 1, wherein a conductive pattern is included at an edge portion of the dummy mold structure.

15. The device of claim 1, further comprising a lower insulation pattern filling a space between the memory cell stack structure and the dummy mold structure; and wherein upper surfaces of the memory cell stack structure, the dummy mold structure, and the lower insulation pattern are substantially coplanar with each other.

16. An integrated circuit device, comprising:
a plurality of circuit patterns on a substrate;
a lower insulating interlayer on the circuit patterns;
base semiconductor patterns on the lower insulating interlayer, said base semiconductor patterns including first and second base semiconductor patterns, which are spaced apart from each other by an opening extending therebetween;
a memory cell stack structure on the base semiconductor patterns;
a channel structure in a channel hole that passes through the memory cell stack structure, said channel structure including a channel electrically connected to an underlying one of the base semiconductor patterns;
a dummy mold structure on the base semiconductor patterns and the first opening, the dummy mold structure being spaced apart from the cell stack structure; and
a lower insulation pattern, which fills a space between the memory cell stack structure and the dummy mold structure, said lower insulation pattern having an upper surface that is substantially coplanar with an upper surface of the memory cell stack structure and an upper surface of the dummy mold structure; and
wherein the dummy mold structure comprises:
a first dummy mold structure including first insulation layers and first sacrificial layers, which are alternately stacked, have upper and lower surfaces that are not planar, and include center portions with dish-shaped cross sections;
a first lower insulation pattern, which fills a dish-shaped recess in an upper surface of the first dummy mold structure; and
an upper dummy mold structure on the first dummy mold structure and the first lower insulation pattern, the upper dummy mold structure including second insulation layers and second sacrificial layers, which are alternately stacked and have substantially planar upper and lower surfaces.

17. The device of claim 16, further comprising a through via contact, which passes through the dummy mold structure and is electrically connected to at least one of the circuit patterns.

18. An integrated circuit device, comprising:
a plurality of circuit patterns on a substrate;
a lower insulating interlayer on the circuit patterns;
a vertical stack of nonvolatile memory cells on a first portion of the lower insulating interlayer, said vertical stack of nonvolatile memory cells including a plurality of electrically insulating layers and a plurality of gate patterns arranged as an alternating stack of electrically insulating layers and gate patterns;
a dummy mold structure on a second portion of the lower insulating interlayer, said dummy mold structure including: a first alternating stack of first electrically insulating layers and first sacrificial layers having respective dish-shaped cross sections, and a second alternating stack of second electrically insulating layers and second sacrificial layers having substantially planar upper and lower surfaces thereon; and
an insulation pattern, which: (i) fills a dish-shaped recess in the first alternating stack of first electrically insulating layers and first sacrificial layers, (ii) has a substantially planar upper surface, and (iii) extends between an uppermost surface of the first alternating stack of first electrically insulating layers and first sacrificial layers and a lowermost surface of the second alternating stack of second electrically insulating layers and second sacrificial layers.

19. The device of claim 18, further comprising a through via contact, which extends through the dummy mold structure and is electrically coupled to at least a first one of the plurality of circuit patterns.

20. The device of claim 18, wherein a portion of the insulation pattern also extends between the vertical stack of nonvolatile memory cells and the dummy mold structure; and wherein an upper surface of the portion of the insulation pattern is coplanar with the substantially planar upper surface.

21. (canceled)

22. (canceled)
